(19) United States
(12) Patent Application Publication
(10) Pub. No.: US 2025/0374712 A1
(43) Pub. Date: Dec. 4, 2025

(54) LIGHT-EMITTING ELEMENT, DISPLAY DEVICE INCLUDING THE SAME, ELECTRONIC DEVICE INCLUDING DISPLAY DEVICE, AND METHOD OF FABRICATING LIGHT-EMITTING ELEMENT

(71) Applicant: Samsung Display Co., LTD., Yongin-si (KR)

(72) Inventors: Chan Woo JOO, Yongin-si (KR); Jun Youn KIM, Yongin-si (KR); Hoo Keun PARK, Yongin-si (KR); Chi Hun WON, Yongin-si (KR); Min Hee LIM, Yongin-si (KR)

(21) Appl. No.: 19/041,597

(22) Filed: Jan. 30, 2025

(30) Foreign Application Priority Data
Jun. 4, 2024 (KR) 10-2024-0073176

(51) Int. Cl. H10H 20/814; H10H 20/01; H10H 20/831; H10H 20/841; H10H 29/80

(52) U.S. Cl. CPC H10H 20/814; H10H 20/032; H10H 20/034; H10H 20/8314; H10H 20/841; H10H 29/8421

(57) ABSTRACT

A light-emitting element includes semiconductor layers including a first semiconductor layer, a light-emitting layer and a second semiconductor layer, a contact electrode disposed on the semiconductor layers, a first reflective layer in which an opening exposing a portion of the contact electrode is defined, the first reflective layer being disposed on a second portion of the contact electrode which is different from the first portion, a conductive adhesive layer disposed on the first portion of the contact electrode, the conductive adhesive layer including a second reflective layer including a material different from that of the first reflective layer, and a bonding electrode disposed on the first reflective layer and the conductive adhesive layer and connected to the contact electrode through the conductive adhesive layer. One surface of the semiconductor layers and the contact electrode is covered with the first reflective layer and the conductive adhesive layer.

This application claims priority to Korean Patent Application No. 10-2024-0073176, filed on Jun. 4, 2024, and all the benefits accruing therefrom under 35 U.S.C. § 119, the content of which in its entirety is herein incorporated by reference.

### BACKGROUND

### Field

The disclosure relates to a light-emitting element, a display device including the same, and a method of fabricating the light-emitting element.

### Description of the Related Art

A light-emitting element is widely used as a light source for various electronic devices including a display device. For example, the light-emitting element is used as a light source for various electronic devices including a virtual reality (“VR”) device or an augmented reality (“AR”) device as well as a portable electronic device or a television.

### BRIEF SUMMARY

Features of the disclosure provide a light-emitting element in which bonding characteristics and light emission efficiency are improved, a display device including the same, and a method of fabricating the light-emitting element.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, there is provided a light-emitting element including semiconductor layers including a first semiconductor layer, a light-emitting layer and a second semiconductor layer, a contact electrode disposed on the semiconductor layers, a first reflective layer in which an opening exposing a first portion of the contact electrode is defined, the first reflective layer being disposed on a second portion of the contact electrode which is different from the first portion, a conductive adhesive layer disposed on the first portion of the contact electrode, the conductive adhesive layer including a second reflective layer including a material different from that of the first reflective layer, and a bonding electrode disposed on the first reflective layer and the conductive adhesive layer and connected to the contact electrode through the conductive adhesive layer. One surface of the semiconductor layers and the contact electrode may be covered with the first reflective layer and the conductive adhesive layer.

In an embodiment, the first reflective layer may include a distributed Bragg reflector that reflects light of a wavelength band of light generated from the light-emitting layer and transmits infrared rays, and the second reflective layer may include metal.

In an embodiment, the conductive adhesive layer may be filled in the opening of the first reflective layer, and the surface of the semiconductor layers and the contact electrode, which is next (adjacent) to the bonding electrode, may be completely covered with the first reflective layer and the conductive adhesive layer.

In an embodiment, the light-emitting element may further include an insulating layer which surrounds sides of the semiconductor layers.

In an embodiment, the light-emitting element may further include a third reflective layer spaced apart from the semiconductor layers with the insulating layer interposed therebetween, surrounding the sides of the semiconductor layers, and the third reflective layer may include metal.

In an embodiment, the first reflective layer may cover an entirety of an upper surface of the semiconductor layers and the contact electrode and the third reflective layer except for a portion of the semiconductor layers and the contact electrode, which is covered with the conductive adhesive layer.

In an embodiment, the insulating layer may further cover an upper surface of the contact electrode except for a portion covered with the conductive adhesive layer.

In an embodiment, the first reflective layer may cover an entirety of the insulating layer.

In an embodiment, the first reflective layer may directly surround the semiconductor layers and the contact electrode except for a portion of the semiconductor layers and the contact electrode, which is covered with the conductive adhesive layer.

In an embodiment, the conductive adhesive layer may have a smaller area than the bonding electrode, and a first portion of the bonding electrode may overlap the conductive adhesive layer, and a second portion of the bonding electrode different from the first portion of the bonding electrode may overlap the first reflective layer.

In an embodiment, the conductive adhesive layer may further include a first adhesive layer disposed between the contact electrode and the second reflective layer and a second adhesive layer disposed between the second reflective layer and the bonding electrode.

In an embodiment, the conductive adhesive layer may further include a first barrier layer disposed between the second reflective layer and the second adhesive layer and a second barrier layer disposed between the second adhesive layer and the bonding electrode.

In an embodiment of the disclosure, there is provided a display device including a pixel including a first electrode, a second electrode and a light-emitting element connected between the first electrode and the second electrode. The light-emitting element may include semiconductor layers including a first semiconductor layer, a light-emitting layer and a second semiconductor layer, a contact electrode disposed between the semiconductor layers and the first electrode, a bonding electrode disposed between the contact electrode and the first electrode, a first reflective layer which is disposed between the contact electrode and the bonding electrode, and in which an opening overlapping a portion of the contact electrode and the bonding electrode is defined, the first reflective layer overlapping a second portion of the contact electrode, which is different from the first portion, and the bonding electrode, and a conductive adhesive layer disposed in the opening of the first reflective layer between the contact electrode and the bonding electrode and including a second reflective layer including a material different from that of the first reflective layer. One surface of the semiconductor layers and the contact electrode, which faces the first electrode, may be covered with the first reflective layer and the conductive adhesive layer.

In an embodiment, the first reflective layer may include a distributed Bragg reflector that reflects light of a wavelength band of light generated from the light-emitting layer and transmits infrared rays, and the second reflective layer may include metal.

In an embodiment, the conductive adhesive layer may be filled in the opening of the first reflective layer, and one surface of the semiconductor layers and the contact electrode, which is next (adjacent) to the bonding electrode, may be completely covered with the first reflective layer and the conductive adhesive layer.

In an embodiment, the light-emitting element may further include an insulating layer which surrounds sides of the semiconductor layers, and a third reflective layer surrounding the sides of the semiconductor layers with the insulating layer interposed therebetween and including metal.

In an embodiment of the disclosure, there is provided a method of fabricating a light-emitting element, the method including sequentially forming semiconductor layers and a contact electrode on a substrate, the semiconductor layers including a first semiconductor layer, a light-emitting layer and a second semiconductor layer, forming a first reflective layer on the semiconductor layers and the contact electrode, defining an opening in the first reflective layer so that a portion of the contact electrode is exposed, forming a conductive adhesive layer, which includes a second reflective layer, inside the opening, and forming a bonding electrode on the first reflective layer and the conductive adhesive layer. The first reflective layer and the second reflective layer may include or consist of different materials from each other.

In an embodiment, the first reflective layer may include or consist of a distributed Bragg reflector, and the second reflective layer may include or consist of metal.

In an embodiment, the method may further include, before forming the first reflective layer, forming an insulating layer covering the semiconductor layers and the contact electrode, and etching the insulating layer to expose at least a portion of the contact electrode.

In an embodiment, the method may further include, forming a third reflective layer on at least a portion of the insulating layer to surround sides of the semiconductor layers and the contact electrode.

According to the light-emitting element and the method of fabricating the same in the embodiments, a conductive adhesive layer, which overlaps a portion of a contact electrode and a bonding electrode and includes a second reflective layer, and a first reflective layer, which overlaps a remaining (the other) portion of the contact electrode and the bonding electrode and includes a material different from that of the second reflective layer, may be disposed between the contact electrode and the bonding electrode of the light-emitting element. In some embodiments, the first reflective layer may include a distributed Bragg reflector that reflects light of a wavelength band, which is generated from a light-emitting layer, and transmits infrared rays, and the second reflective layer may include metal.

In the embodiments, the contact electrode and the bonding electrode may be stably coupled or connected to each other by the conductive adhesive layer, and at the same time, infrared rays used in a bonding process or the like may appropriately reach the bonding electrode by transmitting the first reflective layer, whereby bonding characteristics of the light-emitting element may be improved. In addition, light emitted from the light-emitting element may be reflected by the first reflective layer and the second reflective layer, so that the amount or proportion of light emitted to one end of the light-emitting element disposed on an opposite side of the bonding electrode may be increased. As a result, light emission efficiency of the light-emitting element may be improved.

In some embodiments, the light-emitting element may further include a third reflective layer surrounding sides of semiconductor layers and the contact electrode. Accordingly, light emission efficiency of the light-emitting element may be more improved.

The display device in the embodiments may include a pixel including the light-emitting element. Accordingly, light efficiency of the pixel and the display device including the same may be improved.

However, effects in the embodiments of the disclosure are not limited to those exemplified above and various other effects are incorporated herein.

### BRIEF DESCRIPTION OF THE DRAWINGS

The above and other advantages and features of the disclosure will become more apparent by describing in detail embodiments thereof with reference to the attached drawings, in which:

FIG. 1 is a cross-sectional view illustrating an embodiment of a light-emitting element;

FIG. 2 is an enlarged cross-sectional view illustrating an area A1 of FIG. 1;

FIG. 3 is a cross-sectional view illustrating an embodiment of a first reflective layer;

FIG. 4 is a cross-sectional view illustrating an embodiment of a bonding method of a light-emitting element;

FIG. 5 is a cross-sectional view illustrating an embodiment of a light-emitting element;

FIG. 6 is a cross-sectional view illustrating an embodiment of a light-emitting element;

FIG. 7 is a cross-sectional view illustrating an embodiment of a light-emitting element;

FIG. 8 is a cross-sectional view illustrating an embodiment of a light-emitting element;

FIG. 9 is a cross-sectional view illustrating an embodiment of a light-emitting element;

FIG. 10 is a cross-sectional view illustrating an embodiment of a light-emitting element;

FIGS. 11 to 17 are cross-sectional views illustrating an embodiment of a method of fabricating a light-emitting element;

FIG. 18 is a perspective view illustrating an embodiment of a display device;

FIG. 19 is a perspective view illustrating an embodiment of a display device;

FIG. 20 is a plan view illustrating an embodiment of a display area;

FIG. 21 is a cross-sectional view illustrating an embodiment of a display panel;

FIG. 22 is a cross-sectional view illustrating an embodiment of a display panel;

FIG. 23 is a view illustrating an embodiment of a virtual reality device including a display device;

FIG. 24 is a view illustrating an embodiment of a smart device including a display device;

FIG. 25 is a view illustrating an embodiment of a vehicle dashboard and center fascia including a display device;

FIG. 26 is a view illustrating an embodiment of a transparent display device including a display device; and

FIG. 27 is a block diagram illustrating an embodiment of an electronic device.

### DETAILED DESCRIPTION OF THE DISCLOSURE

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it may be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Features of each of various embodiments of the disclosure may be partially or entirely combined with each other and may technically and variously interwork with each other, and respective embodiments may be implemented independently of each other or may be implemented together in association with each other.

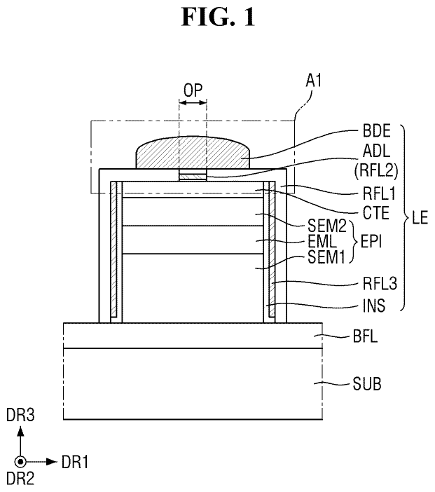

FIG. 1 is a cross-sectional view illustrating an embodiment of a light-emitting element LE. Although FIG. 1 illustrates a state that the light-emitting element LE is disposed on a substrate SUB, the disclosure is not limited thereto. In an embodiment, the light-emitting element LE may be separated from the substrate SUB after being fabricated on the substrate SUB, for example. Also, although FIG. 1 illustrates that only one light-emitting element LE is disposed on the substrate SUB, for example, the disclosure is not limited thereto. In an embodiment, a plurality of light-emitting elements LE may be disposed on the substrate SUB, for example.

Referring to FIG. 1, the light-emitting element LE may be disposed on the substrate SUB. In an embodiment, a buffer layer BFL may be disposed on the substrate SUB, and the light-emitting element LE may be disposed on the buffer layer BFL.

In FIG. 1, a first direction DR1, a second direction DR2 and a third direction DR3 are perpendicular to one another. In an embodiment, the first direction DR1 and the second direction DR2 are perpendicular to each other, and a main surface (e.g., an upper surface) of the substrate SUB may define a parallel plane, for example. The third direction DR3 may be a direction perpendicular to the first direction DR1 and the second direction DR2. In an embodiment, the third direction DR3 is a direction perpendicular to the main surface of the substrate SUB, and may be a height direction or a thickness direction of the substrate SUB or the light-emitting element LE, for example. In an embodiment, the buffer layer BFL and the light-emitting element LE may be sequentially disposed on the substrate SUB along the third direction DR3, for example.

The light-emitting element LE may have various shapes in the embodiments. In an embodiment, the light-emitting element LE may have a circular or quadrangular shape, e.g., rectangular shape in a plan view, for example, but may have other planar shapes. The light-emitting element LE may have a shape of a substantially quadrangular shape (e.g., a rectangular shape, a trapezoid, an inverted trapezoid, etc.) in a cross-section (e.g., a longitudinal section), but may have other cross-sectional shapes. In an embodiment, the light-emitting element LE may have a substantially quadrangular shape, e.g., rectangular shape in a cross-section and include a bonding electrode BDE protruded in the third direction DR3 on an upper surface. A side of the light-emitting element LE may be substantially perpendicular to the substrate SUB, but is not limited thereto. In an embodiment, the light-emitting element LE may have a side shape inclined in an oblique direction with respect to the substrate SUB, for example.

In an embodiment, the light-emitting element LE may be an inorganic light-emitting element including or consisting of an inorganic material. In an embodiment, the light-emitting element LE may be an inorganic light-emitting diode including or consisting of a nitride-based semiconductor material (e.g., GaN, AlGaN, GaAlN, InGaN, AlInGaN, AlN, InN or other nitride-based semiconductor material), a phosphide-based semiconductor material (e.g., GaP, GaInP, AlGaP, AlInP, AlGaInP, AlP, InP or other phosphide-based semiconductor material) or other inorganic material, for example. The light-emitting element LE may emit light of a predetermined color. In an embodiment, the light-emitting element LE may emit red light, green light, blue light or light of another color, for example. The material constituting the light-emitting element LE or the color of light emitted from the light-emitting element LE may vary depending on the embodiments.

In an embodiment, the light-emitting element LE may be a micro light-emitting diode (“micro LED”) having a relatively small size in the range of micrometer (μm). In an embodiment, the light-emitting element LE may be a micro LED in which each of a length (e.g., a horizontal length) in the first direction DR1, a length (e.g., a vertical length) in the second direction DR2 and a length (e.g., a thickness or a height) in the third direction DR3 is several micrometers to several hundreds of micrometers. In an embodiment, each of the length of the light-emitting element LE in the first direction DR1, the length of the light-emitting element LE in the second direction DR2 and the length of the light-emitting element LE in the third direction DR3 may be 100um or less, respectively, but is not limited thereto.

The light-emitting element LE may include semiconductor layers EPI and a contact electrode CTE, which are sequentially disposed on the substrate SUB or the buffer layer BFL, a first reflective layer RFL1 and a conductive adhesive layer ADL, which are disposed on the contact electrode CTE, and a bonding electrode BDE disposed on the first reflective layer REFLI and the conductive adhesive layer ADL. In an embodiment, the light-emitting element LE may further include an insulating layer INS and a third reflective layer RFL3, which surround sides of the semiconductor layers EPI.

The substrate SUB may be a semiconductor substrate used for fabrication of the light-emitting element LE. The substrate SUB may be a fabricating substrate or wafer suitable for epitaxial growth. In an embodiment, the semiconductor layers EPI of the light-emitting element LE may be formed on the substrate SUB through epitaxial growth, for example.

In an embodiment, the substrate SUB may be a substrate including or consisting of a material such as GaAs, silicon (Si), sapphire, SiC, GaN or ZnO. In an embodiment, the substrate SUB may be a silicon or sapphire substrate, for example. When the epitaxial growth for fabricating the light-emitting element LE may be actively performed, a type or material of the substrate SUB is not particularly limited. In an embodiment, the substrate SUB may be used as a substrate for epitaxial growth for fabrication of the light-emitting element LE, and then may be finally separated from the light-emitting element LE. In an embodiment, after a plurality of light-emitting elements LE are simultaneously formed on the substrate SUB through epitaxial growth, the light-emitting elements LE may be separated from the substrate SUB, for example.

The buffer layer BFL may be disposed on the substrate SUB. The buffer layer BFL may be formed to reduce a difference in lattice constants between the semiconductor layers EPI (e.g., the first semiconductor layer SEM1) and the substrate SUB. In an embodiment, the buffer layer BFL may include an undoped semiconductor material. In an embodiment, the buffer layer BFL may include an undoped semiconductor layer (e.g., undoped GaN) including or consisting of a nitride-based semiconductor material, a phosphide-based semiconductor material or other semiconductor material, for example.

The semiconductor layers EPI may include a first semiconductor layer SEM1, a light-emitting layer EML and a second semiconductor layer SEM2, which are sequentially disposed or stacked on the substrate SUB or the buffer layer BFL. In an embodiment, the first semiconductor layer SEM1, the light-emitting layer EML and the second semiconductor layer SEM2 may be sequentially disposed on the buffer layer BFL along the third direction DR3, for example. The semiconductor layers EPI may be also referred to as “semiconductor epitaxial stacks” or “epi-layers”.

The first semiconductor layer SEM1 may include a semiconductor material doped with a first conductivity type dopant. In an embodiment, the first semiconductor layer SEM1 may be a first conductivity type semiconductor layer including or consisting of a nitride-based semiconductor material, a phosphide-based semiconductor material or other semiconductor material and further including or consisting of a first conductivity type dopant, for example. In an embodiment, the first semiconductor layer SEM1 may be an n-type semiconductor layer (e.g., n-GaN) doped with an n-type dopant such as Si, Ge or Sn, but is not limited thereto.

The light-emitting layer EML may be disposed on the first semiconductor layer SEM1. In an embodiment, the light-emitting layer EML may be disposed between the first semiconductor layer SEM1 and the second semiconductor layer SEM2, for example. The light-emitting layer EML may emit light by recombination of an electron-hole pair generated in accordance with an electric signal applied through the first semiconductor layer SEM1 and the second semiconductor layer SEM2.

The light-emitting layer EML may include a nitride-based semiconductor material, a phosphide-based semiconductor material or other semiconductor material, and may have a single or multi-quantum well structure. In an embodiment, the light-emitting layer EML may have a multi-quantum well structure including a quantum well layer including or consisting of InGaN and a barrier layer including or consisting of GaN, AlGaN or GaAlN, but is not limited thereto. In an embodiment, when the light-emitting layer EML includes InGaN, the content of indium (In) may be adjusted to adjust or change a color of light emitted from the light-emitting layer EML.

In an embodiment, the light-emitting layer EML may emit light of a visible light wavelength band, e.g., light of a wavelength band of approximately 400 nanometers (nm) to approximately 900 nm. In an embodiment, the light-emitting layer EML may emit blue light having a peak wavelength in the range of approximately 440 nm to approximately 480 nm, green light having a peak wavelength in the range of approximately 510 nm to approximately 550 nm, or red light having a peak wavelength in the range of approximately 610 nm to approximately 650 nm, for example. The light-emitting layer EML may emit light of another color or another wavelength band other than the above-described color or wavelength band.

The second semiconductor layer SEM2 may include a semiconductor material doped with a second conductivity type dopant. In an embodiment, the second semiconductor layer SEM2 may be a second conductivity type semiconductor layer including or consisting of a nitride-based semiconductor material, a phosphide-based semiconductor material or other semiconductor material and further including or consisting of a second conductivity type dopant, for example. In an embodiment, the second semiconductor layer SEM2 may be a p-type semiconductor layer (e.g., p-GaN) doped with a p-type dopant such as Mg, Zn, Ca, Se or Ba, but is not limited thereto.

The contact electrode CTE may be disposed on the semiconductor layers EPI. In an embodiment, the contact electrode CTE may be disposed on the second semiconductor layer SEM2, for example. The contact electrode CTE may protect the second semiconductor layer SEM2, and may be provided to the light-emitting element LE to actively connect the second semiconductor layer SEM2 to at least one electrode, a circuit element, a line or the like.

In an embodiment, the contact electrode CTE may be entirely disposed on the semiconductor layers EPI. In an embodiment, the contact electrode CTE may be entirely disposed on the second semiconductor layer SEM2, for example. Therefore, the contact electrode CTE may properly or stably protect the second semiconductor layer SEM2, but the disclosure is not limited thereto. The contact electrode CTE may be disposed only on a portion of the semiconductor layers EPI or the second semiconductor layer SEM2.

The contact electrode CTE may include metal, a metal oxide or other conductive material. In an embodiment, the contact electrode CTE may include or consist of a transparent electrode layer including or consisting of a transparent conductive material (e.g., indium tin oxide (“ITO”), indium zinc oxide (“IZO”) or other transparent conductive material), but is not limited thereto.

The first reflective layer RFL1 may be disposed on at least the contact electrode CTE. In an embodiment, the first reflective layer RFL1 may be directly disposed on the contact electrode CTE to contact the contact electrode CTE, for example.

In the embodiments, the first reflective layer RFL1 may define an opening OP that exposes a portion of the contact electrode CTE, and may be disposed on another portion of the contact electrode CTE. In an embodiment, the first reflective layer RFL1 may cover an entirety of an upper surface of the semiconductor layers EPI and the contact electrode CTE except for a portion in which the opening OP is defined.

The first reflective layer RFL1 may or may not surround sides of the semiconductor layers EPI and the contact electrode CTE. In an embodiment, the first reflective layer RFL1 may surround the sides of the semiconductor layers EPI and the contact electrode CTE. In an embodiment, the first reflective layer RFL1 may surround an entirety of or wrap surfaces of the semiconductor layers EPI and the contact electrode CTE except for an area in which the opening OP is defined, for example. In an embodiment, an insulating layer INS and a third reflective layer RFL3 may be disposed between the sides of the semiconductor layers EPI and the contact electrode CTE and the first reflective layer RFL1.

In the embodiments, the first reflective layer RFL1 may include a distributed Bragg reflector (“'DBR”) that reflects light of a predetermined wavelength band and transmits light of another wavelength band, or may include or consist of a DBR. In an embodiment, the first reflective layer RFL1 may reflect light of a wavelength band (e.g., red light, green light or blue light emitted from the light-emitting element LE) generated from the light-emitting layer EML and transmit infrared (“IR”) rays. Therefore, light emission efficiency (or reflectance) and bonding characteristics of the light-emitting element LE may be simultaneously improved.

The conductive adhesive layer ADL may be disposed on the contact electrode CTE. In an embodiment, the conductive adhesive layer ADL may be disposed on a portion of the contact electrode CTE exposed by the opening OP of the first reflective layer RFL1, for example. In an embodiment, the conductive adhesive layer ADL may be directly disposed on the contact electrode CTE to contact the contact electrode CTE.

The conductive adhesive layer ADL may connect the contact electrode CTE with the bonding electrode BDE. The contact electrode CTE and the bonding electrode BDE may be stably coupled or connected to each other by the conductive adhesive layer ADL.

In the embodiments, the conductive adhesive layer ADL may include a second reflective layer RFL2 including or consisting of a material different from that of the first reflective layer RFL1. In an embodiment, the second reflective layer RFL2 may include metal having relatively high light reflectance. In an embodiment, the second reflective layer RFL2 may include or consist of metal including at least one of metals having relatively high reflectance, such as aluminum (Al), molybdenum (Mo), titanium (Ti), copper (Cu), silver (Ag), magnesium (Mg), platinum (Pd), palladium (Pd), gold (Au), nickel (Ni), neodymium (Nd), iridium (Ir) and chromium (Cr), or other reflective material, for example.

In the embodiments, one surface of the semiconductor layers EPI and the contact electrode CTE, which is next (adjacent) to or faces the bonding electrode BDE, may be covered with the first reflective layer RFL1 and the conductive adhesive layer ADL. In an embodiment, the upper surface of the semiconductor layers EPI and the contact electrode CTE, which are disposed toward the bonding electrode BDE, may be covered with the first reflective layer RFL1 and the conductive adhesive layer ADL, for example.

In an embodiment, the conductive adhesive layer ADL may be filled in the opening OP of the first reflective layer RFL1, for example. In addition, when viewed from a plane (or when viewed from the top), the semiconductor layers EPI and the contact electrode CTE may be completely covered with the first reflective layer RFL1 and the conductive adhesive layer ADL. In an embodiment, the conductive adhesive layer ADL may completely fill the opening OP of the first reflective layer RFL1 when viewed from a plane, for example. In addition, the upper surface of the semiconductor layers EPI and the contact electrode CTE, which is next (adjacent) to the bonding electrode BDE, may be completely covered with the first reflective layer RFL1 and the conductive adhesive layer ADL. Therefore, reflectance of light generated by the light-emitting element LE may be increased, and light emission efficiency of the light-emitting element LE (e.g., efficiency of light emitted to the outside of the light-emitting element LE by transmitting one surface of the first semiconductor layer SEM1 separated from the substrate SUB) may be improved.

In an embodiment, the conductive adhesive layer ADL may have an area smaller than that of the bonding electrode BDE. In an embodiment, the conductive adhesive layer ADL may overlap a portion of the bonding electrode BDE, and may not overlap another portion of the bonding electrode BDE, for example. In an embodiment, when viewed from a plane (or when viewed from the top), the conductive adhesive layer ADL completely overlaps the bonding electrode BDE, and may be disposed inside the bonding electrode BDE, for example.

In an embodiment, an overlap area between the conductive adhesive layer ADL and the bonding electrode BDE may be reduced or minimized, so that the bonding characteristics of the light-emitting element LE may be improved. In an embodiment, the conductive adhesive layer ADL (or the opening OP of the first reflective layer RFL1) may have a width or diameter equal to or less than about 1 μm in the first direction DR1 or the second direction DR2, for example. Therefore, the overlap area (or a ratio of the overlap area) between the conductive adhesive layer ADL and the bonding electrode BDE may be reduced or minimized. A size (e.g., a width or an area) of the conductive adhesive layer ADL is not limited to the above-described range, and may be appropriately adjusted or changed in consideration of connection characteristics between the contact electrode CTE and the bonding electrode BDE and the bonding characteristics of the light-emitting element LE.

In an embodiment, the first reflective layer RFL1 may be enlarged as much as the reduced area of the conductive adhesive layer ADL to stably cover the semiconductor layers EPI and the contact electrode CTE. Therefore, it is possible to improve or make sure of reflectance or light emission efficiency of the light-emitting element LE while improving the bonding characteristics of the light-emitting element LE. In an embodiment, IR rays used when the light-emitting element LE is bonded may reach the bonding electrode BDE by transmitting the first reflective layer RFL1, so that the bonding characteristics of the light-emitting element LE may be improved, for example. In addition, light generated from the light-emitting layer EML and directed toward one surface (e.g., the upper surface of FIG. 1) of the light-emitting element LE on which the bonding electrode BDE is disposed may be reflected by the conductive adhesive layer ADL and the first reflective layer RFL1 and thus recirculated. Therefore, light loss occurring in the light-emitting element LE may be avoided or reduced, and light emission efficiency (e.g., a ratio of light emitted to the outside by transmitting one surface of the light-emitting element LE on which the first semiconductor layer SEM1 is disposed) of the light-emitting element LE may be improved.

In an embodiment, the conductive adhesive layer ADL and the first reflective layer RFL1 may be disposed at substantially the same height, and may have substantially the same thickness. In an embodiment, the conductive adhesive layer ADL may be disposed at the same thickness or height as the first reflective layer RFL1 in the opening OP of the first reflective layer RFL1, and a side of the conductive adhesive layer ADL may be surrounded by the first reflective layer RFL1, for example. Therefore, adhesion between the conductive adhesive layer ADL and the first reflective layer RFL1 and the bonding electrode BDE may be improved or obtained, and the bonding electrode BDE may be stably connected to the conductive adhesive layer ADL.

The bonding electrode BDE may be disposed on the first reflective layer RFL1 and the conductive adhesive layer ADL. In an embodiment, a portion (also referred to as a first portion) of the bonding electrode BDE may be disposed on the conductive adhesive layer ADL to overlap the conductive adhesive layer ADL, and a remaining (the other) portion (also referred to as a second portion) of the bonding electrode BDE may be disposed on the first reflective layer RFL1 to overlap the first reflective layer RFL1, for example. In an embodiment, the bonding electrode BDE may be directly disposed on the first reflective layer RFL1 and the conductive adhesive layer ADL.

As the bonding electrode BDE is disposed on the conductive adhesive layer ADL, the bonding electrode BDE may be connected to the contact electrode CTE through the conductive adhesive layer ADL. In an embodiment, the bonding electrode BDE may be connected (e.g., electrically connected) to the conductive adhesive layer ADL through direct or indirect contact, and may be connected (e.g., electrically connected) to the contact electrode CTE through the conductive adhesive layer ADL, for example. The bonding electrode BDE and the contact electrode CTE may be stably coupled or connected to each other by the conductive adhesive layer ADL.

As the bonding electrode BDE is disposed on the first reflective layer RFL1, IR rays or the like used in a bonding process may reach the bonding electrode BDE by transmitting the first reflective layer RFL1. Therefore, heat transfer desired for bonding may be actively performed, and the bonding characteristics of the light-emitting element LE may be improved.

The insulating layer INS may be disposed on the sides of at least the semiconductor layers EPI to surround the sides of the semiconductor layers EPI. In an embodiment, the insulating layer INS may directly surround the sides of the semiconductor layers EPI in contact with the semiconductor layers EPI.

The insulating layer INS may at least partially surround or not surround the sides of the contact electrode CTE. In an embodiment, the insulating layer INS may surround or wrap the sides of the contact electrode CTE in contact with the contact electrode CTE.

The insulating layer INS may include at least one insulating material of silicon oxide (SiOₓ) (e.g., SiO₂), silicon nitride (SiNₓ) (e.g., Si₃N₄), aluminum oxide (AlₓO_{y}) (e.g., Al₂O₃), titanium oxide (TiₓO_{y}) (e.g., TiO₂) and HfOₓ or other insulating material. The insulating layer INS may protect the semiconductor layers EPI and prevent a short circuit defect of the light-emitting element LE to make sure of or improve electrical characteristics of the light-emitting element LE.

The third reflective layer RFL3 may surround the sides of the semiconductor layers EPI. In an embodiment, the third reflective layer RFL3 may be spaced apart from the semiconductor layers EPI with the insulating layer INS interposed therebetween, and may surround the sides of the semiconductor layers EPI, for example.

In an embodiment, the third reflective layer RFL3 may include metal having relatively high light reflectance. In an embodiment, the third reflective layer RFL3 may include at least one of metals having relatively high reflectance, such as aluminum (Al), molybdenum (Mo), titanium (Ti), copper (Cu), silver (Ag), magnesium (Mg), platinum (Pd), palladium (Pd), gold (Au), nickel (Ni), neodymium (Nd), iridium (Ir) and chromium (Cr), or other reflective material, for example. The second reflective layer RFL2 and the third reflective layer RFL3 may include the same material or different materials from each other.

The third reflective layer RFL3 may reflect light generated from the light-emitting layer EML. In an embodiment, the third reflective layer RFL3 may reflect light generated from the light-emitting layer EML and directed toward the side of the light-emitting element LE to recirculate the light, for example. Therefore, loss of the light generated from the light-emitting element LE may be avoided or reduced, and light emission efficiency (e.g., a ratio of light emitted to the outside by transmitting the first semiconductor layer SEM1) of the light-emitting element LE may be further improved.

In an embodiment, the first reflective layer RFL1 may include or consist of multiple insulating layers including or consisting of an insulating material, and may surround or wrap the third reflective layer RFL3. In an embodiment, the first reflective layer RFL1 may cover an entirety of the upper surface of the semiconductor layers EPI and the contact electrode CTE and the third reflective layer RFL3 except for a portion (e.g., a portion of the upper surface that overlaps the bonding electrode BDE) of the semiconductor layers EPI and the contact electrode CTE, which is covered with the conductive adhesive layer ADL, for example. Therefore, the third reflective layer RFL3 may be protected, and a short circuit defect of the light-emitting element LE may be avoided to make sure of or improve electrical characteristics of the light-emitting element LE.

As described above, the light-emitting element LE may include a conductive adhesive layer ADL and a first reflective layer RFL1, which cover one surface of the semiconductor layers EPI and the contact electrode CTE. In an embodiment, one surface of the semiconductor layers EPI and the contact electrode CTE, which is next (adjacent) to the bonding electrode BDE, may be completely covered with the conductive adhesive layer ADL and the first reflective layer RFL1, for example. In addition, the conductive adhesive layer ADL may overlap only a portion (also referred to as a first portion) of the bonding electrode BDE, and a remaining (the other) portion (also referred to as a second portion) of the bonding electrode BDE may overlap the first reflective layer RFL1. Therefore, it is possible to improve the bonding characteristics of the light-emitting element LE while increasing a light emission rate of light generated from the light-emitting element LE.

In an embodiment, the bonding characteristics of the light-emitting element LE may be improved by adjusting or changing the overlap area between the conductive adhesive layer ADL and the bonding electrode BDE. In an embodiment, the overlap area between the conductive adhesive layer ADL and the bonding electrode BDE may be reduced or minimized, and the overlap area between the conductive adhesive layer ADL and the bonding electrode BDE may be increased or maximized as much as the reduced overlap area, for example. Therefore, the amount of IR rays reaching the bonding electrode BDE during bonding of the light-emitting element LE may be increased, and the bonding characteristics of the light-emitting element LE may be effectively improved.

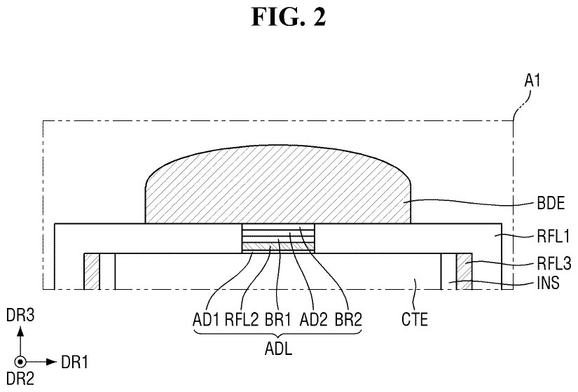

FIG. 2 is an enlarged cross-sectional view illustrating an area A1 of FIG. 1. FIG. 2 shows a structure of a conductive adhesive layer ADL in an embodiment, for example.

Referring to FIGS. 1 and 2, the conductive adhesive layer ADL includes a second reflective layer RFL2, and may further include an additional layer. In an embodiment, the conductive adhesive layer ADL may further include a first adhesive layer AD1 disposed between the contact electrode CTE and the second reflective layer RFL2, and a second adhesive layer AD2 disposed between the second reflective layer RFL2 and the bonding electrode BDE, for example.

The first adhesive layer AD1 and the second adhesive layer AD2 may include a conductive material suitable for improving adhesion, and may include the same conductive material or different conductive materials. In an embodiment, each of the first adhesive layer AD1 and the second adhesive layer AD2 may include metal such as chromium (Cr), but is not limited thereto.

In an embodiment, the conductive adhesive layer ADL may further include at least one barrier layer. In an embodiment, the conductive adhesive layer ADL may further include a first barrier layer BR1 disposed between the second reflective layer RFL2 and the second adhesive layer AD2, and a second barrier layer BR2 disposed between the second adhesive layer AD2 and the bonding electrode BDE, for example.

Each of the first barrier layer BRI and the second barrier layer BR2 may include a conductive material suitable for diffusion barrier (e.g., intermetallic diffusion barrier) or the like, and may include the same conductive material or different conductive materials. In an embodiment, each of the first barrier layer BRI and the second barrier layer BR2 may include metal such as nickel (Ni) having a relatively high intermetallic diffusion barrier effect, but is not limited thereto.

In the embodiments, the conductive adhesive layer ADL may be disposed between the contact electrode CTE and the bonding electrode BDE, so that adhesion between the contact electrode CTE and the bonding electrode BDE may be improved or obtained, and the bonding electrode BDE may be stably connected to the conductive adhesive layer ADL.

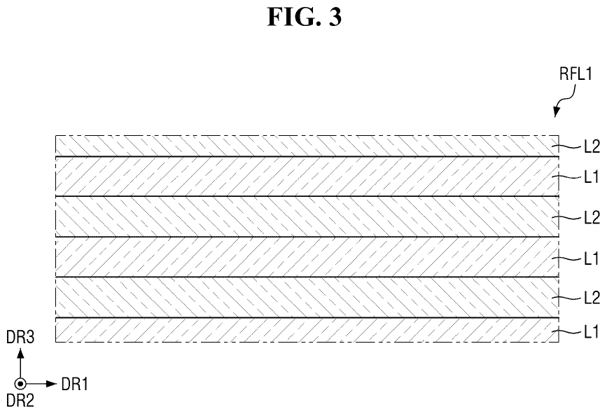

FIG. 3 is a cross-sectional view illustrating an embodiment of a first reflective layer RFL1. FIG. 3 shows a portion of the first reflective layer RFL1 shown in FIGS. 1 and 2, for example.

Referring to FIGS. 1 to 3, the first reflective layer RFL1 may have a multi-layered structure that includes at least one pair of first and second layers L1 and L2. In an embodiment, the first reflective layer RFL1 may include a DBR that includes at least one pair of first and second layers L1 and L2 sequentially or alternately disposed on the contact electrode CTE along the third direction DR3, for example. In an embodiment, the first reflective layer RFL1 may have a plurality of first layers L1 and a plurality of second layers L2, which are alternately disposed on the contact electrode CTE, but is not limited thereto.

The first layer L1 and the second layer L2 may have their respective refractive indexes different from each other. In an embodiment, one of the first layer L1 and the second layer L2 may be a relatively low refractive layer, and a remaining (the other) one thereof may be a relatively high refractive layer, for example.

In one configuration, the first reflective layer RFL1 may include or consist of multiple insulating layers including or consisting of an insulating material. In an embodiment, each of the first layer L1 and the second layer L2 may include or consist of an insulating layer including or consisting of an insulating material, for example. In an embodiment, the first layer L1 and the second layer L2 may include or consist of different materials and/or different thicknesses. In an embodiment, one of the first layer L1 and the second layer L2 includes a silicon oxide such as SiO₂ and may be formed at a thickness of approximately 70nm or more, and a remaining (the other) one of the first layer L1 and the second layer L2 includes a titanium oxide such as TiO₂ and may be formed at a thickness of approximately 40nm or more, for example. In an alternative embodiment, the first layer L1 and the second layer L2 may include the same material, but may have different thicknesses. The materials of the first layer L1 and the second layer L2 are not limited to the exemplified materials. In an embodiment, one of the first layer L1 and the second layer L2 may include a hafnium oxide such as HfO₂, and a remaining (the other) one of the first layer L1 and the second layer L2 may include a titanium oxide such as TiO₂, for example. In an alternative embodiment, one of the first layer L1 and the second layer L2 may include a silicon oxide such as SiO₂, and a remaining (the other) one of the first layer L1 and the second layer L2 may include a silicon nitride such as Si₃N₄. Various modifications may be made in the material of each of the first layer L1 and the second layer L2 or a material combination of the first layer L1 and the second layer L2 depending on the embodiments.

In the embodiments, the material, the thickness or the number of the first layers L1 and the second layers L2 may be adjusted in consideration of a target reflective wavelength, so that optical characteristics of the first reflective layer RFL1 may be appropriately adjusted or changed. In an embodiment, at least one of the material, the thickness or the number of the first layers L1 and the second layers L2 may be adjusted or optimized so that the first reflective layer RFL1 may reflect light corresponding to the wavelength band of the light emitted from the light-emitting element LE at higher reflectance and actively transmit IR rays, for example. In an embodiment, in case of the light-emitting element LE for emitting red light, the first reflective layer RFL1 may properly transmit IR rays while effectively reflecting light of the red wavelength band, for example. Similarly, in case of the light-emitting element LE for emitting green light, the first reflective layer RFL1 may properly transmit IR rays while effectively reflecting light of the green wavelength band. In case of the light-emitting element LE for emitting blue light, the first reflective layer RFL1 may properly transmit IR rays while effectively reflecting light of the blue wavelength band. In an embodiment, the thickness of each layer constituting the first reflective layer RFL1 may be set to mainly reflect light of the target reflective wavelength in accordance with the refractive index of each layer and the target reflective wavelength (e.g., a peak wavelength of light emitted from the light-emitting element LE). In an embodiment, the total thickness of the first reflective layer RFL1 may be set to mainly reflect light of the target reflective wavelength in accordance with the refractive index of the first reflective layer RFL1 and the target reflective wavelength.

In the embodiments, the first reflective layer RFL1 may be disposed between the contact electrode CTE and the bonding electrode BDE, so that the IR rays may appropriately reach the bonding electrode BDE during bonding of the light-emitting element LE. In addition, the light generated from the light-emitting layer EML of the light-emitting element LE may be properly reflected by the first reflective layer RFL1 and the second reflective layer RFL2 to improve or make sure of light emission efficiency of the light-emitting element LE.

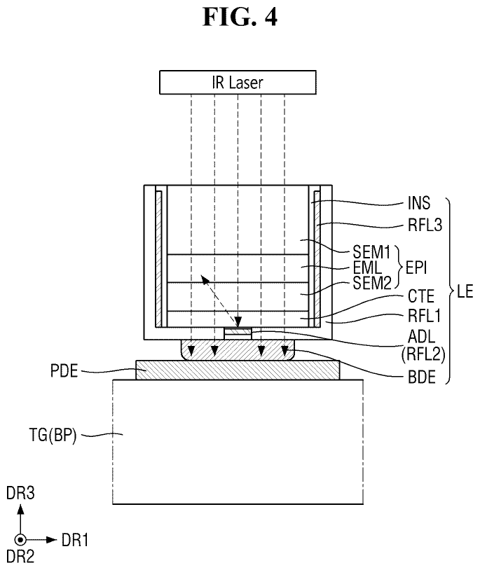

FIG. 4 is a cross-sectional view illustrating an embodiment of a bonding method of a light-emitting element LE.

Referring to FIGS. 1 to 4, the light-emitting element LE may be separated from the substrate SUB and bonded onto a target substrate TG. A pad electrode PDE for connection with the light-emitting element LE may be disposed on the target substrate TG. In an embodiment, the pad electrode PDE may be a bonding pad for bonding the light-emitting element LE onto the target substrate TG, and may include a conductive material (e.g., a bonding metal) for suitable for bonding. In an embodiment, the target substrate TG may be a backplane substrate BP or a lower substrate of the display panel, and the pad electrode PDE may be a first electrode (e.g., a pixel electrode) provided to each pixel of the display panel. The light-emitting element LE may be used as a light source even in other devices in which a light source is desired.

In an embodiment, the light-emitting element LE may be disposed on the target substrate TG so that the bonding electrode BDE is disposed on the pad electrode PDE of the target substrate TG and the light-emitting element LE may be bonded onto the target substrate TG by eutectic bonding using an IR laser. In the embodiments, only a portion (also referred to as a first portion) of the bonding electrode BDE may overlap the conductive adhesive layer ADL, and a remaining (the other) portion (also referred to as a second portion) of the bonding electrode BDE may overlap the first reflective layer RFL1. Therefore, when the light-emitting element LE is bonded onto the target substrate TG by an IR laser or the like, even though a portion (also referred to as a first portion) of the IR rays irradiated to the light-emitting element LE is reflected by the second reflective layer RFL2 of the conductive adhesive layer ADL, a remaining (the other) portion (also referred to as a second portion) of the IR rays may appropriately reach the bonding electrode BDE by transmitting the first reflective layer RFL1. Therefore, heat transfer to the bonding electrode BDE may be appropriately performed so that the bonding characteristics of the light-emitting element LE may be improved, and the light-emitting element LE and the pad electrode PDE may be stably coupled or connected to each other.

As the area of the conductive adhesive layer ADL is reduced, the reflective amount of IR rays may be reduced so that the bonding characteristics of the light-emitting element LE may be appropriately improved. In an embodiment, the area of the conductive adhesive layer ADL (or the overlap ratio of the conductive adhesive layer ADL and the bonding electrode BDE) may be appropriately adjusted in consideration of adhesion and electrical characteristics (e.g., contact resistance) between the contact electrode CTE and the bonding electrode BDE and the bonding characteristics of the light-emitting element LE.

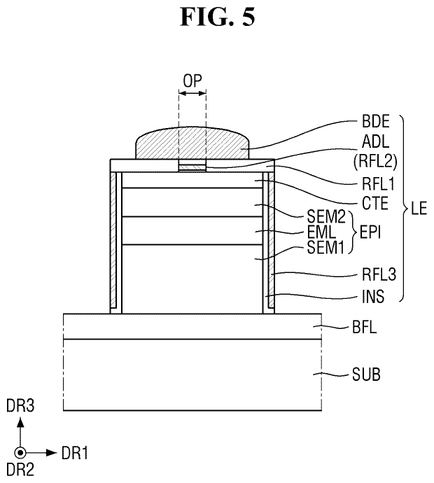

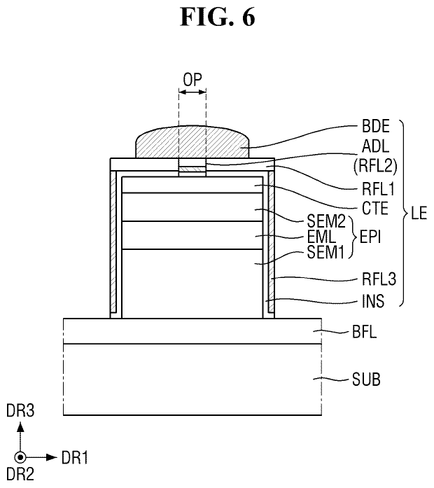

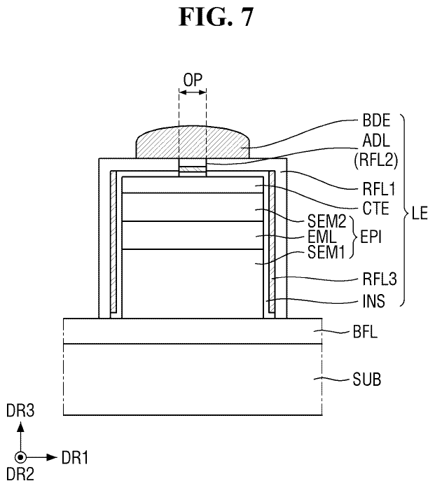

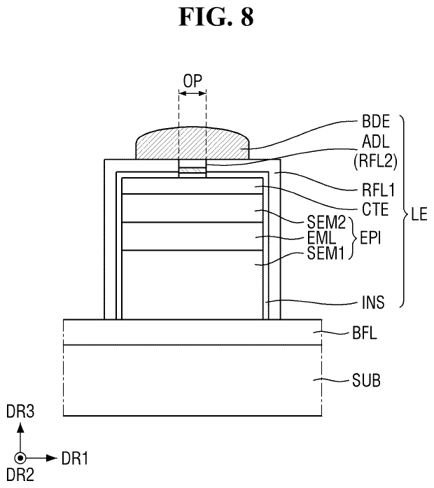

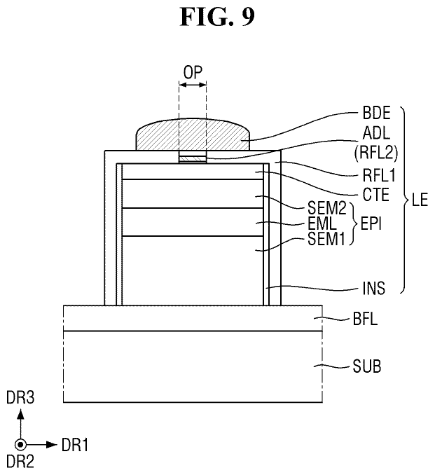

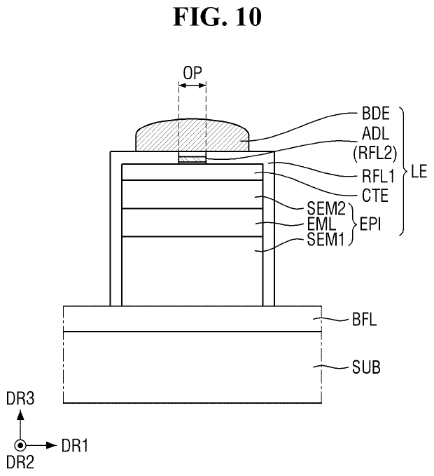

FIG. 5 is a cross-sectional view illustrating an embodiment of a light-emitting element LE. FIG. 6 is a cross-sectional view illustrating a light-emitting element LE. FIG. 7 is a cross-sectional view illustrating an embodiment of a light-emitting element LE. FIG. 8 is a cross-sectional view illustrating an embodiment of a light-emitting element LE. FIG. 9 is a cross-sectional view illustrating an embodiment of a light-emitting element LE. FIG. 10 is a cross-sectional view illustrating an embodiment of a light-emitting element LE. FIGS. 5 to 10 show different modified embodiments of the embodiments of FIGS. 1 to 3 in connection with the first reflective layer RFL1, the insulating layer INS and the third reflective layer RFL3, for example. In describing the embodiments, redundant descriptions of similar or identical elements may be omitted.

Referring to FIGS. 1 to 5, the first reflective layer RFL1 may be disposed only on the upper surface of the semiconductor layers EPI and the contact electrode CTE, and may not be disposed on the sides of the semiconductor layers EPI and the contact electrode CTE. In an embodiment, the first reflective layer RFL1 may not surround a side of the third reflective layer RFL3, for example. Light generated from the light-emitting layer EML, moving toward the upper surface of the semiconductor layers EPI and the contact electrode CTE may be reflected by the first reflective layer RFL1 and the second reflective layer RFL2. The generated from the light-emitting layer EML, moving toward the sides of the semiconductor layers EPI and the contact electrode CTE may be reflected by the third reflective layer RFL3. Therefore, light emission efficiency of the light-emitting element LE may be improved or obtained.

Referring to FIGS. 6 and 7 in addition to FIGS. 1 to 5, the insulating layer INS may be also disposed on the contact electrode CTE. In an embodiment, the insulating layer INS may be provided not only on the sides of the semiconductor layers EPI and the contact electrode CTE but also on the upper surface of the contact electrode CTE, thereby appropriately protecting the contact electrode CTE, for example. In an embodiment, the insulating layer INS may further cover the upper surface of the contact electrode CTE except for a portion covered with the conductive adhesive layer ADL, for example.

The first reflective layer RFL1 may be disposed on the upper surface of at least the semiconductor layers EPI and the contact electrode CTE, and may or may not be disposed on the sides of the semiconductor layers EPI and the contact electrode CTE. In an embodiment, the first reflective layer RFL1 may be disposed only on the upper surface of the semiconductor layers EPI and the contact electrode CTE as shown in FIG. 6, or may be also disposed on the sides of the semiconductor layers EPI and the contact electrode CTE as shown in FIG. 7, for example. In an embodiment, the first reflective layer RFL1 may cover the third reflective layer RFL3, and may appropriately protect the third reflective layer RFL3.

Referring to FIGS. 8 and 9 in addition to FIGS. 1 to 7, the light-emitting element LE may not include the third reflective layer RFL3, and the first reflective layer RFL1 may be disposed on the upper surface and the sides of the semiconductor layers EPI and the contact electrode CTE. In an embodiment, the first reflective layer RFL1 may cover an entirety of the surface of the semiconductor layers EPI and the contact electrode CTE except for a portion in which the conductive adhesive layer ADL is disposed, for example. In addition, the first reflective layer RFL1 may cover an entirety of the insulating layer INS.

Even though the light-emitting element LE does not include the third reflective layer RFL3, the light generated from the light-emitting layer EML and directed toward the side of the light-emitting element LE may be reflected by the third reflective layer RFL3. Therefore, light emission efficiency of the light-emitting element LE may be appropriately improved or obtained.

Referring to FIG. 10 in addition to FIGS. 1 to 9, the light-emitting element LE may not include an insulating layer INS and a third reflective layer RFL3, and the semiconductor layers EPI and the contact electrode CTE may be covered with the first reflective layer RFL1. In an embodiment, the first reflective layer RFL1 may be disposed on the upper surface and the sides of the semiconductor layers EPI and the contact electrode CTE to contact the semiconductor layers EPI and the contact electrode CTE, for example. In addition, the first reflective layer RFL1 may directly surround the semiconductor layers EPI and the contact electrode CTE except for a portion of the semiconductor layers EPI and the contact electrode CTE, which is covered with the conductive adhesive layer ADL. Even though the light-emitting element LE does not include the insulating layer INS and the third reflective layer RFL3, the semiconductor layers EPI and the contact electrode CTE may be properly protected by the first reflective layer RFL1, and the light generated from the light-emitting layer EML may be properly reflected by the first reflective layer RFL1.

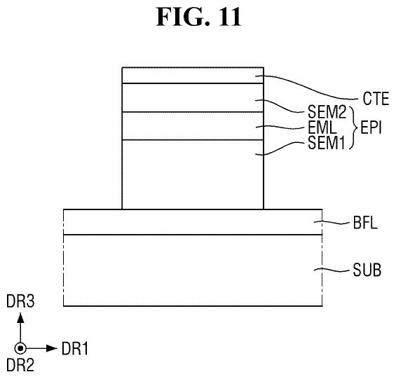

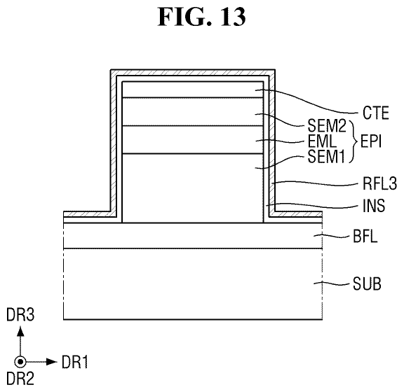

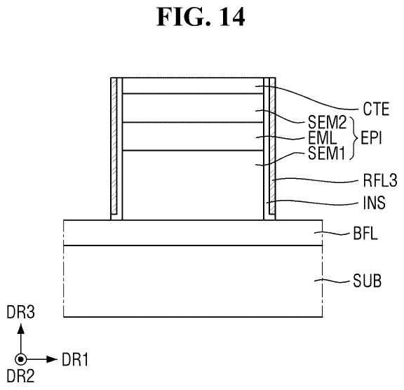

FIGS. 11 to 17 are cross-sectional views illustrating an embodiment of a method of fabricating a light-emitting element LE. In an embodiment, FIGS. 11 to 17 sequentially illustrate an embodiment of fabricating steps for fabricating the light-emitting element LE in the embodiments of FIGS. 1 to 3, for example. Each light-emitting element LE in the embodiments of FIGS. 5 to 10 may be fabricated in a manner substantially similar to that of the light-emitting element LE in the embodiments of FIGS. 1 to 3. In an embodiment, each light-emitting element LE according to FIGS. 5 to 10 may be fabricated in a manner similar to that of the light-emitting element LE in the embodiments of FIGS. 1 to 3 except that a position or area in which some elements are formed is modified or a process of forming some elements is omitted, for example.

Referring to FIG. 11, a substrate SUB for fabricating the light-emitting element LE may be prepared, and semiconductor layers EPI, which include a first semiconductor layer SEM1, a light-emitting layer EML and a second semiconductor layer SEM2, and a contact electrode CTE may be sequentially formed on the substrate SUB. In an embodiment, a buffer layer BFL may be first formed on the substrate SUB, and the first semiconductor layer SEM1, the light-emitting layer EML, the second semiconductor layer SEM2 and the contact electrode CTE may be sequentially formed on the buffer layer BFL.

The substrate SUB may be a semiconductor substrate suitable for epitaxial growth. The substrate SUB may be a semiconductor substrate including or consisting of the above-described material.

The buffer layer BFL may include or consist of a semiconductor material exemplified above, and may be entirely formed on the substrate SUB through epitaxial growth. In an embodiment, the buffer layer BFL may be formed on the substrate SUB by epitaxial growth using a process technology such as metal-organic chemical vapor deposition (“MOCVD”), metal-organic vapor phase epitaxy (“MOVPE”), molecular beam epitaxy (“MBE”), liquid phase epitaxy (“LPE”) or vapor phase epitaxy (“VPE”), for example.

The semiconductor layers EPI may include or consist of the semiconductor material exemplified above, and may be sequentially formed on the buffer layer BFL (or the substrate SUB) by epitaxial growth. The semiconductor layers EPI may be formed entirely on the buffer layer BFL and then etched in a size and/or shape corresponding to each light-emitting element LE.

In an embodiment, the first semiconductor layer SEM1 may be formed on the buffer layer BFL by epitaxial growth using the nitride-based or phosphide-based semiconductor material or other semiconductor material as described above, for example. The first semiconductor layer SEM1 may be doped to include or consist of a first conductivity-type dopant (e.g., an n-type dopant).

The light-emitting layer EML may be formed on the first semiconductor layer SEM1 by epitaxial growth using the nitride-based or phosphide-based semiconductor material or other semiconductor material as described above. In an embodiment, a barrier layer and a quantum well layer may be alternately and/or repeatedly formed on the first semiconductor layer SEM1, so that the light-emitting layer EML having a multi-quantum well structure may be formed.

The second semiconductor layer SEM2 may be formed on the light-emitting layer EML by epitaxial growth using the nitride-based or phosphide-based semiconductor material or other semiconductor material as described above. The second semiconductor layer SEM2 may be doped to include a second conductive type dopant (e.g., a p-type dopant).

The contact electrode CTE may be formed on the semiconductor layers EPI by the transparent conductive material described above or other conductive material. In an embodiment, the contact electrode CTE may be formed by completely depositing a transparent conductive material or other conductive material on the substrate SUB on which the semiconductor layers EPI are formed and then etching the same, for example. In an embodiment, the contact electrode CTE may be formed on the second semiconductor layer SEM2, and may be etched in a shape and/or size corresponding to the second semiconductor layer SEM2, but is not limited thereto. In an embodiment, the contact electrode CTE and the semiconductor layers EPI may be sequentially or substantially simultaneously etched using one mask, or the contact electrode CTE and the semiconductor layers EPI may be sequentially etched using different masks. In an embodiment, the contact electrode CTE may be formed on the substrate on which the semiconductor layers EPI are entirely formed and the contact electrode CTE and the semiconductor layers EPI may be sequentially or substantially simultaneously etched, or the contact electrode CTE may be formed on the semiconductor layers EPI after etching of the semiconductor layers EPI is completed, for example.

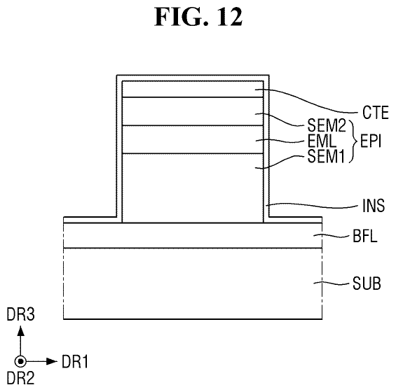

Referring to FIGS. 12 to 14, an insulating layer INS and a third reflective layer RFL3 may be formed on at least one portion of the semiconductor layers EPI and the contact electrode CTE. In an embodiment, as shown in FIG. 12, the insulating layer INS may be formed entirely on the substrate SUB to cover the semiconductor layers EPI and the contact electrode CTE, for example. The insulating layer INS may include or consist of the insulating material exemplified above or other insulating material. Afterwards, the third reflective layer RFL3 may be entirely formed on the insulating layer INS. The third reflective layer RFL3 may include or consist of the above-described material, e.g., metal having relatively high reflectance. Then, at least a portion of the contact electrode CTE may be exposed by etching the insulating layer INS and the third reflective layer RFL3. In an embodiment, the insulating layer INS and the third reflective layer RFL3 may be entirely etched, so that an upper surface of the contact electrode CTE may be exposed and the insulating layer INS and the third reflective layer RFL3 may be formed on sides of the semiconductor layers EPI and the contact electrode CTE, for example.

Positions and/or shapes of the insulating layer INS and the third reflective layer RFL3 may vary depending on the embodiments. In an embodiment, the insulating layer INS may be formed on the upper surface and sides of the semiconductor layers EPI and the contact electrode CTE, or may be formed only on the sides of the semiconductor layers EPI and the contact electrode CTE, for example. In an embodiment, when the light-emitting element LE that does not include the insulating layer INS is formed, a process of forming the insulating layer INS may be omitted. In an embodiment, the third reflective layer RFL3 may be formed on at least a portion of the insulating layer INS to surround the sides of the semiconductor layers EPI and the contact electrode CTE, and may be separated from the semiconductor layers EPI and the contact electrode CTE by the insulating layer INS. When the light-emitting element LE that does not include the third reflective layer RFL3 is formed, a process of forming the third reflective layer RFL3 may be omitted.

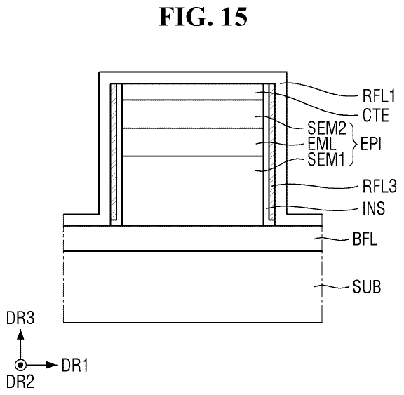

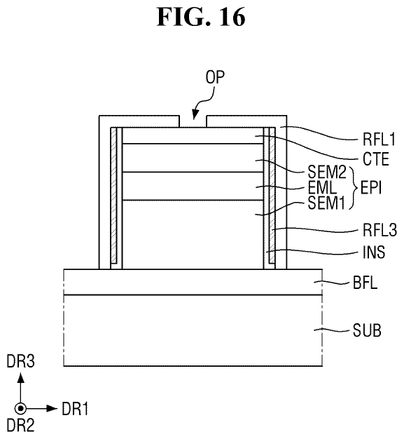

Referring to FIGS. 15 and 16, a first reflective layer RFL1 may be formed on the semiconductor layers EPI and the contact electrode CTE. In an embodiment, as shown in FIG. 15, the first reflective layer RFL1 may be formed entirely on the substrate SUB to cover the semiconductor layers EPI, the contact electrode CTE, the insulating layer INS and the third reflective layer RFL3, for example. Afterwards, as shown in FIG. 16, the first reflective layer RFL1 may be etched in a size and/or shape corresponding to each light-emitting element LE, and at the same time the first reflective layer RFL1 on a portion of the contact electrode CTE may be etched so that an opening OP exposing a portion of the contact electrode CTE may be defined in the first reflective layer RFL1. In the embodiments, the first reflective layer RFL1 may be formed on at least the upper surface of the contact electrode CTE, and may be selectively further formed on the sides of the semiconductor layers EPI and the contact electrode CTE.

In the embodiments, the first reflective layer RFL1 may include or consist of a DBR. In an embodiment, as shown in FIG. 3, at least one pair of first and second layers L1 and L2 having different materials and/or thicknesses may be sequentially and/or alternately formed, and the at least one pair of first and second layers L1 and L2 may be etched to form the first reflective layer RFL1, for example.

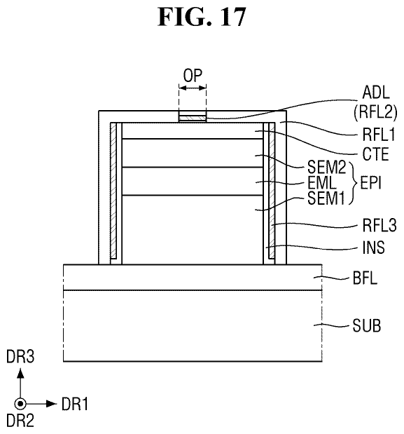

Referring to FIG. 17, a conductive adhesive layer ADL including a second reflective layer RFL2 may be formed in the opening OP of the first reflective layer RFL1. In an embodiment, the conductive adhesive layer ADL including the first adhesive layer AD1, the second reflective layer RFL2, the first barrier layer BR1, the second adhesive layer AD2 and the second barrier layer BR2 of FIG. 2 may be formed in the opening OP of the first reflective layer RFL1, for example. In an embodiment, the conductive adhesive layer ADL may include or consist of metal. In an embodiment, the opening OP of the first reflective layer RFL1 may be filled with the first adhesive layer AD1, the second reflective layer RFL2, the first barrier layer BR1, the second adhesive layer AD2 and the second barrier layer BR2 by the materials exemplified as those of the first adhesive layer AD1, the second reflective layer RFL2, the first barrier layer BR1, the second adhesive layer AD2 and the second barrier layer BR2, for example. In the embodiments, the second reflective layer RFL2 may include or consist of a material and/or a structure, which is different from that of the first reflective layer RFL1. In an embodiment, the first reflective layer RFL1 may include or consist of a DBR capable of transmitting IR rays, while the second reflective layer RFL2 may include or consist of metal having relatively high reflectance, for example.

After the conductive adhesive layer ADL is formed, the bonding electrode BDE shown in FIG. 1 or the like may be formed on the first reflective layer RFL1 and the conductive adhesive layer ADL. In an embodiment, the bonding electrode BDE may be formed on the first reflective layer RFL1 and the conductive adhesive layer ADL by a conductive material (e.g., bonding metal) suitable for bonding, for example. In the embodiments, the bonding electrode BDE may be formed to have an area larger than that of the conductive adhesive layer ADL, and a portion (also referred to as a first portion) and a remaining (the other) portion (also referred to as a second portion) of the bonding electrode BDE may be formed to overlap the conductive adhesive layer ADL and the first reflective layer RFL1, respectively.

In an embodiment, when the light-emitting element LE (or the light-emitting elements LE) separated from the substrate SUB is fabricated or the light-emitting element LE is moved to a backplane substrate of a display panel, a process of separating the light-emitting element LE from the substrate SUB and the buffer layer BFL may be additionally performed. In an embodiment, the substrate SUB and the buffer layer BFL may be separated from the light-emitting element LE by an electrical and/or chemical etching method, a laser lift-off method or other method.

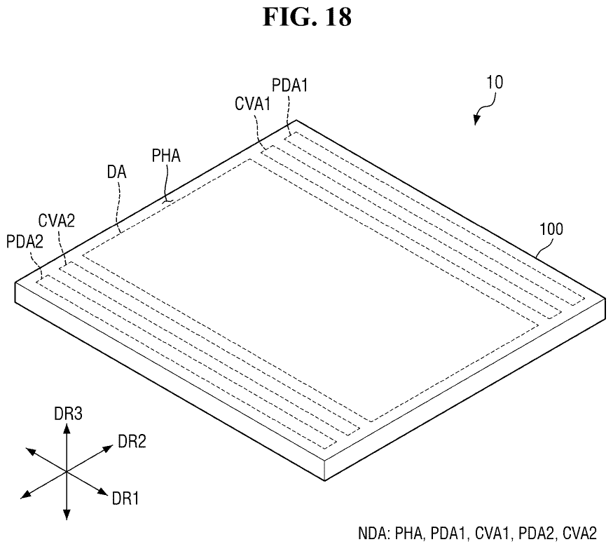

FIG. 18 is a perspective view illustrating an embodiment of a display device 10.

Referring to FIG. 18, the display device 10 in an embodiment may include a display panel 100 that includes a display area DA and a non-display area NDA. In an embodiment, the display device 10 may be a micro-display device applied to a virtual reality device or an augmented reality device, but is not limited thereto.

The display panel 100 may have a quadrangular planar shape, e.g., rectangular planar shape having a long side in a first direction DR1 and a short side in a second direction DR2. In FIG. 18, the first direction DR1 may indicate a horizontal direction of the display panel 100, and the second direction DR2 may indicate a vertical direction of the display panel 100. A third direction DR3 may indicate a thickness direction or a height direction of the display panel 100. However, a planar shape of the display panel 100 is not limited to the quadrangular planar shape, e.g., rectangular planar shape, and the display panel 100 may have other shapes. In an embodiment, the display panel 100 may have another polygonal shape in addition to the quadrangular shape, e.g., rectangular shape, a circular shape, an oval shape or an irregular planar shape, for example.

The display area DA is an area in which an image is displayed, and may include pixels. In an embodiment, the planar shape of the display area DA may follow the planar shape of the display panel 100. FIG. 1 illustrates that the planar shape of the display area DA has a quadrangular shape, e.g., rectangular shape. The display area DA may be disposed in a central area of the display panel 100.

The non-display area NDA is an area in which an image is not displayed, and may be disposed around the display area DA. In an embodiment, the non-display area NDA may surround the display area DA, for example.

The non-display area NDA may include a first common voltage supply area CVA1, a second common voltage supply area CVA2, a first pad area PDA1, a second pad area PDA2 and a peripheral area PHA.

The first common voltage supply area CVA1 may be disposed between the first pad area PDA1 and the display area DA. The second common voltage supply area CVA2 may be disposed between the second pad area PDA2 and the display area DA. In an embodiment, the display panel 100 may include only one of the first common voltage supply area CVA1 and the second common voltage supply area CVA2.

Each of the first common voltage supply area CVA1 and the second common voltage supply area CVA2 may include common electrode connection portions electrically connected to a common electrode disposed in the display area DA. The common electrode connection portions may be further connected to common voltage pads disposed in the first pad area PDA1 and/or the second pad area PDA2. The common electrode connection portions may include a conductive material (e.g., a metallic material such as aluminum (Al)), and may electrically connect the common electrode of the display area DA to the common voltage pads of the first pad area PDA1 and/or the second pad area PDA2. A common voltage (or a relatively low potential pixel voltage) applied to the first pad area PDA1 and/or the second pad area PDA2 may be supplied to the light-emitting elements of the pixels through the common electrode connection portions. FIG. 18 illustrates the display device 10 in which the first common voltage supply area CVA1 and the second common voltage supply area CVA2 are disposed in the non-display area NDA, but the disclosure is not limited thereto. In an embodiment, at least one of the first common voltage supply area CVA1 or the second common voltage supply area CVA2 may be disposed in the display area DA, for example.

The first pad area PDA1 may be disposed on one side (e.g., an upper side) of the display panel 100. The first pad area PDA1 may include common voltage pads connected to an external circuit board.

The second pad area PDA2 may be disposed on an opposite side (e.g., a lower side) of the display panel 100. The second pad area PDA2 may include common voltage pads connected to the external circuit board. In an embodiment, the display panel 100 may include only one of the first pad area PDA1 and the second pad area PDA2.

The peripheral area PHA may be an area other than the first common voltage supply area CVA1, the second common voltage supply area CVA2, the first pad area PDA1 and the second pad area PDA2 in the non-display area NDA. The peripheral area PHA may surround not only the display area DA but also the first common voltage supply area CVA1, the second common voltage supply area CVA2, the first pad area PDA1 and the second pad area PDA2.

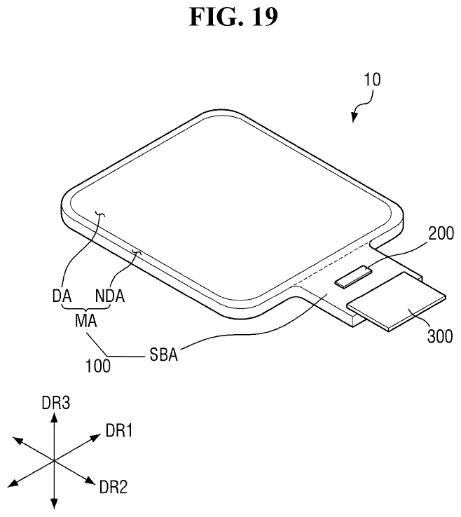

FIG. 19 is a perspective view illustrating an embodiment of a display device 10.

Referring to FIG. 19, the display device 10 includes a display panel 100, a display driving circuit 200 and a circuit board 300. In an embodiment, the display device 10 may be a display device applied to a watch or the like, but is not limited thereto.

The display panel 100 may have a quadrangular planar shape, e.g., rectangular planar shape having a long side in the first direction DR1 and a short side in the second direction DR2. In an embodiment, the display panel 100 may have a substantially quadrangular, e.g., rectangular or square planar shape, for example. A corner at which the long side and the short side of the display panel 100 meet may be rounded to have a predetermined curvature or formed at a right angle. The planar shape of the display panel 100 is not limited to the quadrangular shape, e.g., rectangular shape, and various modifications may be made in the planar shape of the display panel 100 depending on the embodiments. In an embodiment, the display panel 100 may have a planar shape having a different polygonal shape other than the quadrangular shape, e.g., rectangular shape, a circular shape, an oval shape or other shape, for example.

The display panel 100 may include a main area MA that includes a display area DA and a non-display area NDA. The display area DA is an area in which an image is displayed, and may include pixels. The non-display area NDA is disposed around the display area DA, and may surround the display area DA.

In an embodiment, the display panel 100 may further include a sub-area SBA extended from the main area MA. In an embodiment, the sub-area SBA may be extended from one end of the main area MA in the second direction DR2, and may have a width or length smaller than that of the main area MA in at least one of the first direction DR1 or the second direction DR2. Although FIG. 19 illustrates a state that the sub-area SBA is unfolded in parallel with the main area MA, the sub-area SBA may be folded or bent. In an embodiment, the sub-area SBA may be folded at a portion next (adjacent) to the main area MA, and thus a portion of the sub-area SBA may overlap the main area MA, for example. In an embodiment, a portion of the sub-area SBA on which the display driving circuit 200 or the like is packaged may be disposed on a rear surface of the main area MA, for example.

The display driving circuit 200 may be disposed in the sub-area SBA, but its position is not limited thereto. In an embodiment, the display driving circuit 200 may be packaged on another circuit board electrically connected to the display panel 100, for example.

The display driving circuit 200 may generate driving signals for driving the display panel 100. In an embodiment, the display driving circuit 200 may include or consist of an integrated circuit (“IC”), and may be attached onto the display panel 100 by a chip on glass (“COG”) method, a chip on plastic (“COP”) method, an ultrasonic bonding method or other method.

The circuit board 300 may be attached onto one end portion of the display panel 100. In an embodiment, the circuit board 300 may be attached onto a pad portion of the display panel 100, which is disposed at one end portion of the sub-area SBA, and may be electrically connected to the display panel 100 and the display driving circuit 200, for example.

Signals and power voltages for driving the display panel 100 may be supplied to the display panel 100 and the display driving circuit 200 through the circuit board 300. The circuit board 300 may be a flexible printed circuit board, a printed circuit board or a flexible film such as a chip on film, but is not limited thereto.

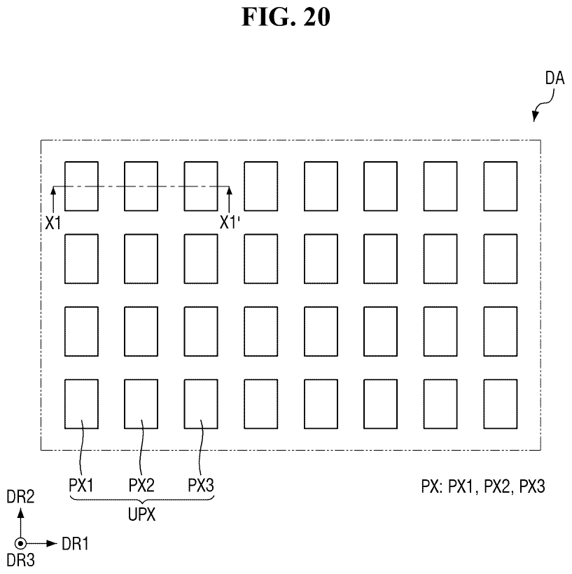

FIG. 20 is a plan view illustrating an embodiment of a display area DA. In an embodiment, FIG. 20 schematically shows the embodiment of pixels PX disposed in the display area DA of FIGS. 18 or 19, for example.

Referring to FIGS. 18 to 20, the display panel 100 may include pixels PX arranged in the display area DA. In an embodiment, the display panel 100 may include first pixels PX1 (e.g., first color subpixels) for emitting light of a first color, second pixels PX2 (e.g., second color subpixels) for emitting light of a second color, and third pixels PX3 (e.g., third color subpixels) for emitting light of a third color. In an embodiment, the first color may be red, the second color may be green and the third color may be blue, but the disclosure is not limited thereto. At least one first pixel PX1, at least one second pixel PX2 and at least one third pixel PX3, which are next (adjacent) to one another, may constitute each unit pixel UPX capable of emitting light of various colors. Various modifications may be made in the number, a type and/or an arrangement structure of pixels PX constituting the unit pixel UPX depending on the embodiments.

Each pixel PX may include at least one light-emitting element LE. In an embodiment, each pixel PX may include a light-emitting element LE according to at least one of the above-described embodiments. In an embodiment, as shown in FIGS. 1 to 10, each pixel PX may include a light-emitting element LE that includes a first reflective layer RFL1 which is disposed between the contact electrode CTE and the bonding electrode BDE and in which an opening OP is defined and a conductive adhesive layer ADL disposed in the opening OP and including a second reflective layer RFL2, for example.

The pixels PX may include light-emitting elements LE that emit light of the same color, or may include light-emitting elements LE that emit light of different colors. In an embodiment, the first pixels PX1, the second pixels PX2 and the third pixels PX3 include light-emitting elements LE that emit light of the same color (e.g., blue light), and wavelength conversion patterns (e.g., wavelength conversion patterns including quantum dots) and/or color filters for converting or controlling a color of light emitted from the light-emitting elements LE provided to each pixel PX may be disposed in light emission areas of the first pixels PX1, the second pixels PX2 and/or the third pixels PX3, for example. In an alternative embodiment, the first pixels PX1, the second pixels PX2 and the third pixels PX3 may include light-emitting elements LE that emit light of a first color, light of a second color and light of a third color, respectively. The pixels PX may include light-emitting elements LE of substantially the same size, or may include light-emitting elements LE of different sizes.

In an embodiment, the pixels PX may be arranged in the display area DA in a matrix form, a stripe form or other form. The sizes of the pixels PX (or the light emission areas of the pixels PX) may be substantially the same as or different from each other. Various modifications may be made in the arrangement shape, the position or the size of the pixels PX depending on the embodiments.

In an embodiment, the pixels PX may have a quadrangular planar shape, e.g., rectangular planar shape such as a rectangle or a rhombus, but the disclosure is not limited thereto. In an embodiment, the pixels PX may have a polygonal shape other than the quadrangular shape, e.g., rectangular shape, a circular shape, an oval shape or other planar shape, for example.

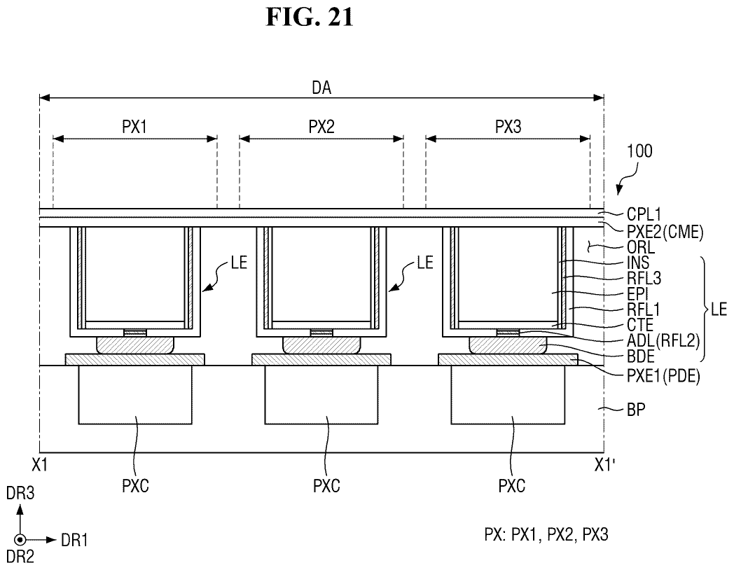

FIG. 21 is a cross-sectional view illustrating an embodiment of a display panel 100. In an embodiment, FIG. 21 shows an embodiment of a cross-section of the display panel 100, which corresponds to line X1-X1′ of FIG. 20, and shows schematic cross-sections of a first pixel PX1, a second pixel PX2 and a third pixel PX3, which are next (adjacent) to one another in the first direction DR1, for example.

FIG. 21 shows an embodiment of a display device 10 that is a light-emitting diode on silicon (“LEDOS”) in which light-emitting diodes are disposed as light-emitting elements LE on a semiconductor circuit board (e.g., a backplane substrate BP or a semiconductor substrate of the display panel 100, in which a pixel circuit PXC or the like is formed based on a silicon wafer) formed by a semiconductor process using a silicon wafer, but the device including the light-emitting elements LE in the embodiments is not limited thereto. In an embodiment, the light-emitting elements LE fabricated in the embodiments may be applied to display devices of different types and/or structures, or may be applied to devices of different types and/or structures, such as lighting devices, for example.

Referring to FIGS. 1 to 20, the display panel 100 may include a backplane substrate BP and light-emitting elements LE disposed on the backplane substrate BP. In addition, the display panel 100 may further include first pixel electrodes PXE1 and second pixel electrodes PXE2, which are connected to the light-emitting elements LE, an organic layer ORL disposed around the light-emitting elements LE, and a first capping layer CPL1 covering the light-emitting elements LE and the second pixel electrode PXE2.

The backplane substrate BP may include a display area DA in which pixels PX are arranged. In an embodiment, the backplane substrate BP may be a semiconductor circuit board formed by a semiconductor process using a silicon wafer. In an embodiment, the silicon wafer may be used as a base member for forming the display panel 100, for example. In an embodiment, the backplane substrate BP may include pixel circuits PXC provided to the display area DA.

The backplane substrate BP may further include the non-display area NDA shown in FIGS. 18 or 19. In an embodiment, the backplane substrate BP may further include conductive patterns (e.g., common electrode connection portions), lines, pads or the like, which are disposed in the non-display area NDA.

Each pixel PX may include a first electrode PXE1, a second electrode PXE2 and a light-emitting element LE connected between the first electrode PXE1 and the second electrode PXE2. In an embodiment, each pixel PX may further include a pixel circuit PXC connected to the first electrode PXE1.

The pixel circuits PXC may be provided to the display area DA to correspond to an area in which each of the pixels PX is formed. In an embodiment, each of the pixel circuits PXC may include a complementary metal-oxide semiconductor (“CMOS”) circuit formed on the backplane substrate BP (or the semiconductor substrate) by a semiconductor process.

Each of the pixel circuits PXC may include at least one transistor formed through the semiconductor process. In addition, each of the pixel circuits PXC may further include at least one capacitor formed through the semiconductor process.

The pixel circuit PXC of each pixel PX may be electrically connected to the first electrode PXE1 of the corresponding pixel PX. Each of the pixel circuits PXC may apply a first pixel voltage (e.g., a relatively high potential pixel voltage) to the first electrode PXE1 connected thereto.

The first electrodes PXE1 of the pixels PX may be disposed on the backplane substrate BP. In an embodiment, the first electrodes PXE1 may be pad electrodes PDE connected to the respective light-emitting elements LE by a bonding process or the like, for example. The first electrodes PXE1 may be single-layered or multi-layered electrodes including or consisting of at least one conductive material. In an embodiment, each first electrode PXE1 may be electrically connected to the pixel circuit PXC of the corresponding pixel PX. In addition, each of the first electrodes PXE1 may be electrically connected to the bonding electrode BDE of the light-emitting element LE provided to the corresponding pixel PX. In an embodiment, each of the first electrodes PXE1 may connect the pixel circuit PXC of the corresponding pixel PX to the light-emitting element LE, for example.

At least one light-emitting element LE may be disposed on the first electrode PXE1 of each pixel PX. Each of the light-emitting elements LE may be disposed or bonded on each of the first electrodes PXE1. In an embodiment, the light-emitting element LE of each pixel PX may be disposed or bonded on the first electrode PXE1 of the corresponding pixel PX so that the bonding electrode BDE is bonded to the first electrode PXE1 of the corresponding pixel PX, for example. The light-emitting element LE of each pixel PX may emit light by a voltage applied to the first electrode PXE1 and the second electrode PXE2 of the corresponding pixel PX.

Each light-emitting element LE may include semiconductor layers EPI, a contact electrode CTE, a first reflective layer RFL1, a conductive adhesive layer ADL and a bonding electrode BDE, as in the embodiments described in FIGS. 1 to 10. The semiconductor layers EPI may include a first semiconductor layer SEM1, a light-emitting layer EML and a second semiconductor layer SEM2. The contact electrode CTE may be disposed between the semiconductor layers EPI and the first electrode PXE1. The bonding electrode BDE may be disposed between the contact electrode CTE and the first electrode PXE1. The first reflective layer RFL1 and the conductive adhesive layer ADL are disposed between the contact electrode CTE and the bonding electrode BDE, and may overlap different portions of the contact electrode CTE and the bonding electrode BDE. In an embodiment, an opening OP that overlaps a portion of the contact electrode CTE and the bonding electrode BDE is defined in the first reflective layer RFL1 which overlaps another portion of the contact electrode CTE and the bonding electrode BDE, and the conductive adhesive layer ADL may be disposed in the opening OP of the first reflective layer RFL1 to overlap a portion of the contact electrode CTE and the bonding electrode BDE, for example. The conductive adhesive layer ADL may include a second reflective layer RFL2 including or consisting of a material different from that of the first reflective layer RFL1.

In the embodiments, one surface (e.g., a lower surface next (adjacent) to the bonding electrode BDE) of the semiconductor layers EPI and the contact electrode CTE, which faces the first electrode PXE1, may be covered with the first reflective layer RFL1 and the conductive adhesive layer ADL. Therefore, light generated from the light-emitting element LE may be reflected by the first reflective layer RFL1 and the second reflective layer RFL2 and emitted upward from the pixel PX. In an embodiment, each light-emitting element LE may further include at least one of an insulating layer INS or a third reflective layer RFL3. In an embodiment, each light-emitting element LE may further include an insulating layer INS and a third reflective layer RFL3, which surrounds sides of the semiconductor layers EPI and the contact electrode CTE, for example. Therefore, light emission efficiency of the light-emitting element LE may be further improved.

In an embodiment, the first pixel PX1, the second pixel PX2 and the third pixel PX3 may include light-emitting elements LE that emit light of different colors. In an embodiment, the light-emitting element LE of the first pixel PX1 may be a first color light-emitting diode (e.g., a red light-emitting diode) that emits light of a first color, and the light-emitting element LE of the second pixel PX2 may be a second color light-emitting diode (e.g., a green light-emitting diode) that emits light of a second color, for example. The light-emitting element LE of the third pixel PX3 may be a third color light-emitting diode (e.g., a blue light-emitting diode) that emits light of a third color.

In an embodiment, at least one insulating layer may be disposed around the light-emitting elements LE. In an embodiment, an organic layer ORL may be disposed around the light-emitting elements LE. In an embodiment, the organic layer ORL may be a filler filled between the light-emitting elements LE. In an embodiment, the organic layer ORL may be formed to have substantially the same height as or similar height to that of the light-emitting elements LE to mitigate a step difference due to the light-emitting elements LE. The organic layer ORL may include an organic insulating material. In an embodiment, the organic layer ORL may include an acrylic resin, an epoxy resin, a phenolic resin, a polyamide resin, a polyimide resin or other organic insulating material, for example.

The second electrode PXE2 may be disposed on the light-emitting elements LE. In an embodiment, the second electrodes PXE2 of the pixels PX may be disposed on the light-emitting elements LE and the organic layer ORL, and may be connected to each other and thus formed as one common electrode CME, but is not limited thereto.

The second electrode PXE2 may be disposed on the semiconductor layers EPI of the light-emitting elements LE. In an embodiment, the second electrode PXE2 may be disposed on the first semiconductor layer SEM1 so that it may be connected to the first semiconductor layer SEM1 shown in FIG. 1, for example. The second electrode PXE2 may include a conductive material. In an embodiment, the second electrode PXE2 may be transparent or translucent. Therefore, the light generated from the light-emitting elements LE may be emitted upward from the pixels PX by transmitting the second electrode PXE2.

The first capping layer CPL1 may be disposed on the second electrode PXE2. The first capping layer CPL1 may be entirely disposed on at least the display area DA, and may cover an entirety of the first pixel electrodes PXE1, the light-emitting elements LE, the organic layer ORL and the second electrode PXE2, which are disposed on the backplane substrate BP. In an embodiment, the first capping layer CPL1 may be an inorganic insulating layer including or consisting of at least one inorganic insulating material suitable for blocking moisture permeation or the like. In an embodiment, the first capping layer CPL1 may include silicon oxide (SiOₓ), silicon nitride (SiNₓ), aluminum oxide (AlₓO_{y}), titanium oxide (TiₓO_{y}) or other inorganic insulating material, for example.

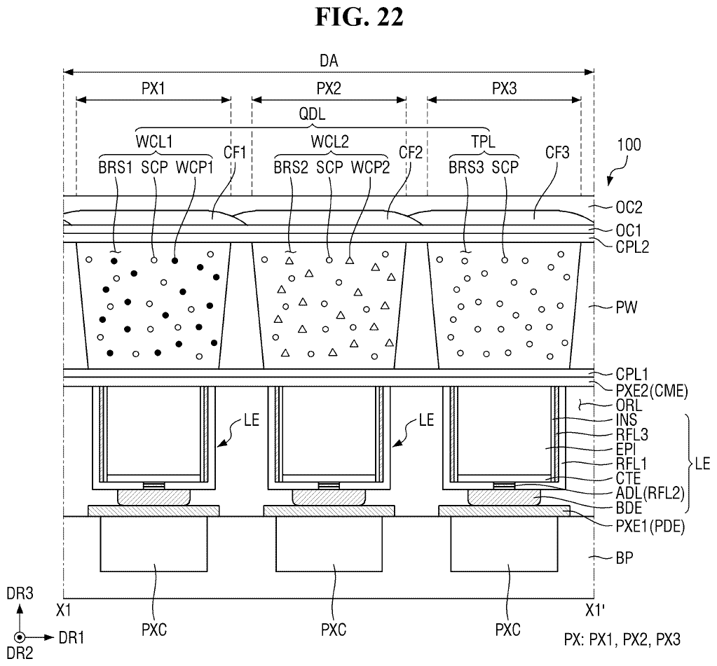

FIG. 22 is a cross-sectional view illustrating an embodiment of a display panel 100. In an embodiment, FIG. 22 shows an embodiment of a cross-section of the display panel 100 corresponding to line X1-X1′ of FIG. 20, and shows schematic cross-sections of a first pixel PX1, a second pixel PX2 and a third pixel PX3, which are next (adjacent) to one another in the first direction DR1, for example. As compared with the embodiment of FIG. 21, the display panel 100 in the embodiment of FIG. 22 further includes an additional element disposed on the first capping layer CPL1.

Referring to FIGS. 1 to 22, the display panel 100 may further include a wavelength conversion layer QDL and color filters. In an embodiment, the display panel 100 may further include a wavelength conversion layer QDL and a partition wall PW, which are disposed on the first capping layer CPL1, a second capping layer CPL2 disposed on the wavelength conversion layer QDL and the partition wall PW, a first overcoat layer OC1 disposed on the second capping layer CPL2, color filters (e.g., a first color filter CF1, a second color filter CF2 and a third color filter CF3) disposed on the first overcoat layer OC1, and a second overcoat layer OC2, for example.

The partition wall PW may partition or define light emission areas in which the wavelength conversion layer QDL is provided. In an embodiment, openings corresponding to the light emission areas of the pixels PX may be defined in the partition wall PW which may surround the light emission areas, for example.

In an embodiment, the partition wall PW may be formed with a relatively thick thickness to provide a space in which the wavelength conversion layer QDL is formed. In an embodiment, the thickness of the partition wall PW may be in the range of 1 μm to 10 μm, for example. In an embodiment, the partition wall PW may include an organic insulating material (e.g., an epoxy resin, an acrylic resin, a cardo resin, an imide resin or other organic insulating material). In an embodiment, the partition wall PW may further include a light-blocking material. In an embodiment, the partition wall PW may include a dye or a pigment, which has light-blocking properties, for example.

The wavelength conversion layer QDL may be disposed in the light emission areas of the pixels PX partitioned by the partition wall PW. The wavelength conversion layer QDL may convert light of a predetermined color emitted from the light-emitting element LE of each pixel PX into light of another color or transmit light of a predetermined color emitted from the light-emitting element LE without converting it into light of another color.

In an embodiment, the wavelength conversion layer QDL may include a first wavelength conversion pattern WCL1 provided to the first pixel PX1, a second wavelength conversion pattern WCL2 provided to the second pixel PX2, and a light-transmissive pattern TPL provided to the third pixel PX3. The first wavelength conversion pattern WCL1, the second wavelength conversion pattern WCL2 and the light-transmissive pattern TPL may be disposed on the light-emitting elements LE to overlap the light-emitting element LE of the first pixel PX1, the light-emitting element LE of the second pixel PX2 and the light-emitting element LE of the third pixel PX3, respectively.

The first wavelength conversion pattern WCL1 may convert light of a predetermined color (e.g., blue light) emitted from the light-emitting element LE of the first pixel PX1 into light of a first color (e.g., red light). The light of the first color converted by the first wavelength conversion pattern WCL1 may be emitted to the outside of the first pixel PX1 (e.g., an upper portion of the display panel 100) by transmitting the first color filter CF1.

The first wavelength conversion pattern WCL1 may include a first base resin BRS1 and first wavelength conversion particles WCP1. In an embodiment, the first wavelength conversion pattern WCL1 may further include scatterers SCP.

The first base resin BRS1 may include a transmissive organic material. In an embodiment, the first base resin BRS1 may include an epoxy resin, an acrylic resin, a cardo resin, or an imide resin, for example.

The first wavelength conversion particles WCP1 may convert the light emitted from the light-emitting element LE of the first pixel PX1 into light of the first color (e.g., red light). In an embodiment, the first wavelength conversion particle WCP1 may be a quantum dot (e.g., a red quantum dot), a quantum rod, a fluorescent material or a phosphorescent material, but is not limited thereto.

The scatterers SCP provided to the first wavelength conversion pattern WCL1 may scatter the light emitted from the light-emitting element LE of the first pixel PX1 in a random direction. The scatterers SCP may have a refractive index different from that of the first base resin BRS1 and form an optical interface with the first base resin BRS1. In an embodiment, the scatterers SCP may be light scattering particles, for example. In an embodiment, the scatterers SCP may be metal oxide particles or organic particles, but are not limited thereto.

The second wavelength conversion pattern WCL2 may convert light of a predetermined color (e.g., blue light) emitted from the light-emitting element LE of the second pixel PX2 into light of the second color (e.g., green light). The light of the second color converted by the first wavelength conversion pattern WCL1 may be emitted to the outside (e.g., the upper portion of the display panel 100) of the second pixel PX2 by transmitting the second color filter CF2.

The second wavelength conversion pattern WCL2 may include a second base resin BRS2 and second wavelength conversion particles WCP2. In an embodiment, the second wavelength conversion pattern WCL2 may further include scatterers SCP.

The second base resin BRS2 may include a light-transmissive organic material. In an embodiment, the second base resin BRS2 may include an epoxy resin, an acrylic resin, a cardo resin or an imide resin, for example. In an embodiment, the second base resin BRS2 may include the same material as that of the first base resin BRS1, but is not limited thereto.

The second wavelength conversion particles WCP2 may convert light emitted from the light-emitting element LE of the second pixel PX2 into light of the second color (e.g., green light). In an embodiment, the second wavelength conversion particle WCP2 may be a quantum dot (e.g., a green quantum dot), a quantum rod, a fluorescent material or a phosphorescent material, but is not limited thereto.

The scatterers SCP provided to the second wavelength conversion pattern WCL2 may scatter the light emitted from the light-emitting element LE of the second pixel PX2 in a random direction. The scatterers SCP may have a refractive index different from that of the second base resin BRS2 and form an optical interface with the second base resin BRS2. In an embodiment, the scatterers SCP may be light scattering particles, for example. In an embodiment, the scatterers SCP may be metal oxide particles or organic particles, for example, but are not limited thereto.

The light-transmissive pattern TPL may transmit incident light. In an embodiment, the light-transmissive pattern TPL may transmit light (e.g., blue light) emitted from the light-emitting element LE of the third pixel PX3 as it is, for example. The light-transmissive pattern TPL may include a third base resin BRS3 and scatterers SCP dispersed in the third base resin BRS3.

The third base resin BRS3 may include a light-transmissive organic material. In an embodiment, the third base resin BRS3 may include an epoxy resin, an acrylic resin, a cardo resin, or an imide resin, for example. In an embodiment, the third base resin BRS3 may include the same material as at least one of the first base resin BRS1 or the second base resin BRS2, but is not limited thereto.

The scatterers SCP provided to the light-transmissive pattern TPL may scatter light emitted from the light-emitting element LE of the third pixel PX3 in a random direction. The scatterers SCP may have a refractive index different from that of the third base resin BRS3 and form an optical interface with the third base resin BRS3. In an embodiment, the scatterers SCP may be light scattering particles, for example. In an embodiment, the scatterers SCP may be metal oxide particles or organic particles, but are not limited thereto. In an embodiment, the scatterers SCP provided to the first wavelength conversion pattern WCL1, the second wavelength conversion pattern WCL2 and the light-transmissive pattern TPL may be the same material or type of particles, but are not limited thereto.

The second capping layer CPL2 may be disposed on the wavelength conversion layer QDL and the partition wall PW. The second capping layer CPL2 may cover the wavelength conversion layer QDL and the partition wall PW to protect the wavelength conversion layer QDL and the partition wall PW from moisture or particles. In an embodiment, the second capping layer CPL2 may include at least one inorganic insulating material. In an embodiment, the second capping layer CPL2 may include the same material as that of the first capping layer CPL1, but is not limited thereto.

In an embodiment, the first overcoat layer OC1 may be disposed on the second capping layer CPL2. The first overcoat layer OC1 may be entirely disposed in the display area DA, and its surface may be flat. In an embodiment, the first overcoat layer OC1 may include a light-transmissive organic material. In an embodiment, the first overcoat layer OC1 may include an epoxy resin, an acrylic resin, a cardo resin, or an imide resin, for example.

The color filters may be disposed on the first overcoat layer OC1. In an embodiment, the first color filter CF1, the second color filter CF2 and the third color filter CF3 may be disposed on the first overcoat layer OC1, for example.

The first color filter CF1 may be provided to the first pixel PX1 to overlap the light-emitting element LE and/or the first wavelength conversion pattern WCL1 of the first pixel PX1. The second color filter CF2 may be provided to the second pixel PX2 to overlap the light-emitting element LE and/or the second wavelength conversion pattern WCL2 of the second pixel PX2. The third color filter CF3 may be provided to the third pixel PX3 to overlap the light-emitting element LE and/or the light-transmissive pattern TPL of the third pixel PX3.

The first color filter CF1, the second color filter CF2 and the third color filter CF3 may selectively transmit light corresponding to a color or wavelength band to be emitted from each pixel PX, and may absorb light of another color or wavelength band. In an embodiment, the first color filter CF1, the second color filter CF2 and the third color filter CF3 may selectively transmit light of a first color, light of a second color and light of a third color, respectively, and may absorb light of another color. In an embodiment, the first color filter CF1, the second color filter CF2 and the third color filter CF3 may be a red color filter, a green color filter and a blue color filter, respectively, for example, but are not limited thereto.

The second overcoat layer OC2 may be disposed on the color filters. The second overcoat layer OC2 may be entirely disposed in the display area DA, and its surface may be flat. In an embodiment, the second overcoat layer OC2 may include a light-transmissive organic material. In an embodiment, the second overcoat layer OC2 may include an epoxy resin, an acrylic resin, a cardo resin, or an imide resin, for example. In an embodiment, the second overcoat layer OC2 may include the same material as that of the first overcoat layer OC1, but is not limited thereto.

The display device 10 in the embodiments of FIGS. 18 to 22 may include a pixel PX that includes a light-emitting element LE (or a light-emitting element LE fabricated in the embodiments of FIGS. 11 to 17) according to at least one of the embodiments of FIGS. 1 to 10. Therefore, light emission efficiency of the pixel PX and the display device 10 including the same may be improved.

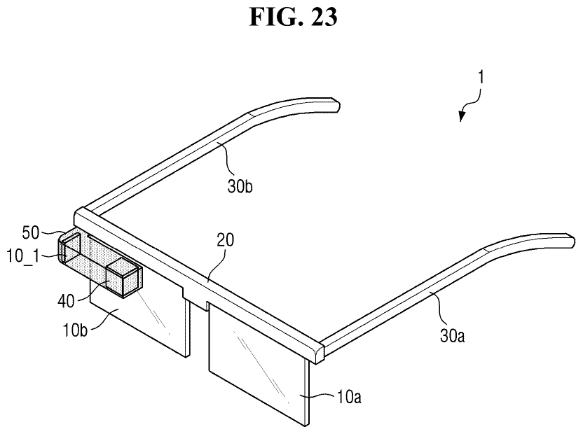

FIG. 23 is a view illustrating an electronic device such as a virtual reality device 1 including a display device 10_1.

Referring to FIG. 23, the virtual reality device 1 in an embodiment may be a glasses-type device. The virtual reality device 1 in an embodiment may include a display device 10_1, a left-eye lens 10a, a right-eye lens 10b, a support frame 20, glasses frame legs 30a and 30b, a reflective member 40, and a display device accommodating portion 50.

Although FIG. 23 illustrates the virtual reality device 1 including the glasses frame legs 30a and 30b, the virtual reality device 1 in an embodiment may be applied to a head disposed (e.g., mounted) display that includes a head mounting band, which may be disposed (e.g., mounted) on a head, instead of the glasses frame legs 30a and 30b. In an embodiment, the virtual reality device 1 is not limited to the embodiment of the form shown in FIG. 21, and is applicable to various electronic devices in various forms, for example.

The display device accommodating portion 50 may include the display device 10_1 and the reflective member 40. An image displayed on the display device 10_1 may be reflected by the reflective member 40 and provided to a user's right eye through the right-eye lens 10b. Therefore, the user may view a virtual reality image displayed on the display device 10_1 through the right eye.

Although FIG. 23 illustrates that the display device accommodating portion 50 is disposed at a right end of the support frame 20, the disclosure is not limited thereto. In an embodiment, the display device accommodating portion 50 may be disposed at a left end of the support frame 20, and in this case, the image displayed on the display device 10_1 may be reflected by the reflective member 40 and provided to the user's left eye through the left-eye lens 10a, for example. Therefore, the user may view the virtual reality image displayed on the display device 10_1 through the left eye. In an alternative embodiment, the display device accommodating portion 50 may be disposed at both the left end and the right end of the support frame 20, and in this case, the user may view the virtual reality image displayed on the display device 10_1 through both the left eye and the right eye.

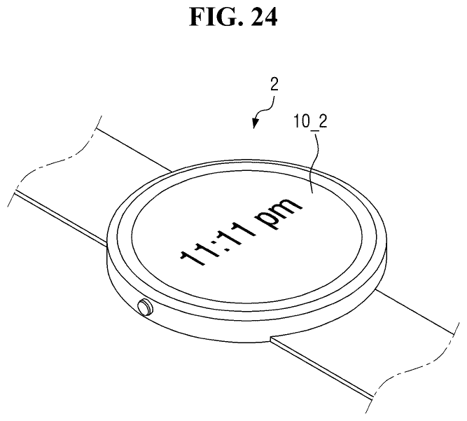

FIG. 24 is a view illustrating an embodiment of an electronic device such as a smart device including a display device 10_2.

Referring to FIG. 24, the display device 10_2 in an embodiment may be applied to a smart watch 2 that is one of smart devices. A planar shape of a clock display unit of the smart watch 2 may follow a planar shape of the display device 10_2. In an embodiment, when the display device 10_2 in an embodiment has a circular planar shape or an oval planar shape, the clock display unit of the smart watch 2 may have a circular planar shape or an oval planar shape, for example. In an alternative embodiment, when the display device 10_2 in an embodiment has a quadrangular planar shape, e.g., rectangular planar shape, the clock display unit of the smart watch 2 may have a quadrangular planar shape, e.g., rectangular planar shape, but the disclosure is not limited thereto. The clock display unit of the smart watch 2 may not follow the planar shape of the display device 10_2.

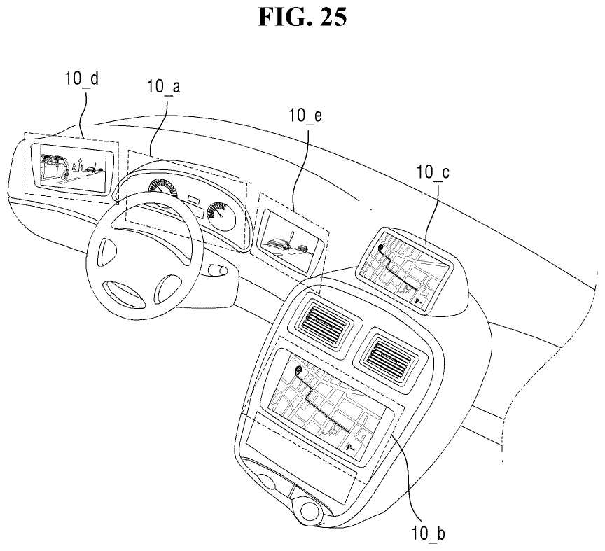

FIG. 25 is a view illustrating an electronic device such as a vehicle dashboard and a center fascia including display devices 10_a, 10_b, 10_c, 10_d and 10_e. A vehicle to which the display devices 10_a, 10_b, 10_c, 10_d and 10_e in an embodiment are applied is shown in FIG. 25.

Referring to FIG. 25, the display devices 10_a, 10_b and 10_c in an embodiment may be applied to a dashboard of the vehicle, applied to a center fascia of the vehicle, or applied to a center information display (“CID”) disposed on the dashboard of the vehicle. In an alternative embodiment, the display devices 10_d and 10_e in an embodiment may be applied to a room mirror display that replaces a side mirror of the vehicle.

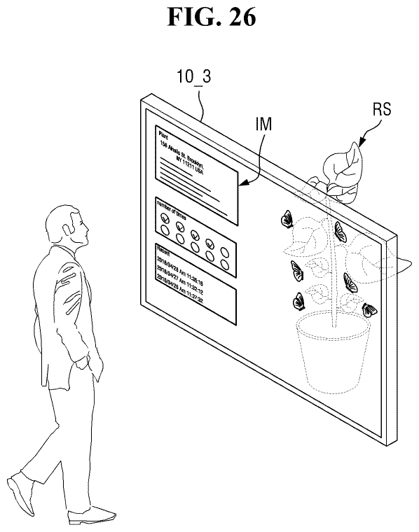

FIG. 26 is a view illustrating an embodiment of an electronic device such as a transparent display device including a display device 10_3.

Referring to FIG. 26, the display device 10_3 in an embodiment may be applied to the transparent display device. The transparent display device may display an image IM and at the same time transmit light. Therefore, a user disposed in front of the transparent display device may not only view the image IM displayed on the display device 10_3 but also view an object RS or background disposed behind the transparent display device. When the display device 10_3 is applied to the transparent display device, the display panel 100 may include a light-transmitting portion capable of transmitting light or may be formed on a substrate member including or consisting of a material capable of transmitting light.

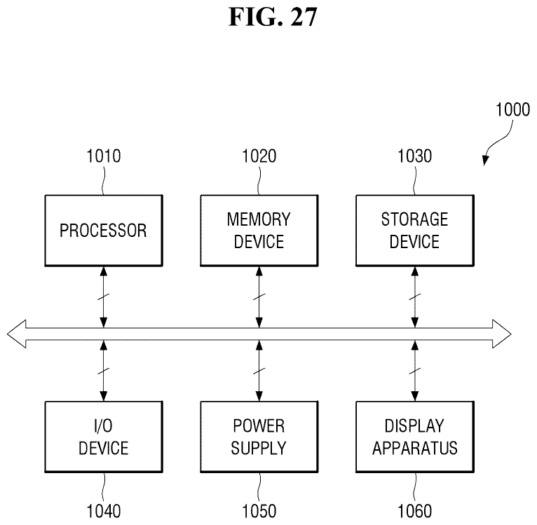

FIG. 27 is a block diagram illustrating an embodiment of an electronic device. Referring to FIG. 27, in an embodiment, an electronic device 1000 may include a processor 1010, a memory device 1020, a storage device 1030, an input/output (“I/O”) device 1040, a power supply 1050, and a display device 1060. Here, the electronic device 1000 may correspond to the virtual reality device 1 in FIG. 23, the smart watch 2 in FIG. 24, or the vehicle dashboard and the center fascia in FIG. 25, for example, and the display device 1060 may correspond to the display device 10 in FIGS. 18 and 19, the display device 10_1 in FIG. 23, the display device 10_2 in FIG. 24, or the display devices 10_a, 10_b, 10_c, 10_d and 10_e in FIG. 25, for example. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a tablet PC, a vehicle display, a computer monitor, a notebook computer, a head-mounted display device, etc. In addition, the electronic device 1000 may be a television, a monitor, a notebook computer, or a tablet. In addition, the electronic device 1000 may be a car.

In concluding the detailed description, those skilled in the art will appreciate that many variations and modifications may be made to the embodiments without substantially departing from the principles of the invention. Therefore, the disclosed embodiments of the invention are used in a generic and descriptive sense only and not for purposes of limitation.

What is claimed is:

1. A light-emitting element comprising:
semiconductor layers including:
a first semiconductor layer;
a light-emitting layer; and
a second semiconductor layer;
a contact electrode disposed on the semiconductor layers;
a first reflective layer in which an opening exposing a first portion of the contact electrode is defined, the first reflective layer being disposed on a second portion of the contact electrode which is different from the first portion;
a conductive adhesive layer disposed on the first portion of the contact electrode, the conductive adhesive layer including:
a second reflective layer including a material different from a material of the first reflective layer; and
a bonding electrode disposed on the first reflective layer and the conductive adhesive layer and connected to the contact electrode through the conductive adhesive layer,
wherein a surface of the semiconductor layers and the contact electrode is covered with the first reflective layer and the conductive adhesive layer.

2. The light-emitting element of claim 1, wherein the first reflective layer includes a distributed Bragg reflector which reflects light of a wavelength band of light generated from the light-emitting layer and transmits infrared rays, and
the second reflective layer includes metal.

3. The light-emitting element of claim 1, wherein the conductive adhesive layer is filled in the opening of the first reflective layer, and
the surface of the semiconductor layers and the contact electrode, which is next to the bonding electrode, is completely covered with the first reflective layer and the conductive adhesive layer.

4. The light-emitting element of claim 1, further comprising an insulating layer surrounding sides of the semiconductor layers.

5. The light-emitting element of claim 4, further comprising a third reflective layer spaced apart from the semiconductor layers with the insulating layer interposed therebetween, surrounding the sides of the semiconductor layers,
wherein the third reflective layer includes metal.

6. The light-emitting element of claim 5, wherein the first reflective layer covers an entirety of an upper surface of the semiconductor layers and the contact electrode and the third reflective layer except for a portion of the semiconductor layers and the contact electrode, which is covered with the conductive adhesive layer.

7. The light-emitting element of claim 4, wherein the insulating layer further covers an upper surface of the contact electrode except for a portion covered with the conductive adhesive layer.

8. The light-emitting element of claim 4, wherein the first reflective layer covers an entirety of the insulating layer.

9. The light-emitting element of claim 1, wherein the first reflective layer directly surrounds the semiconductor layers and the contact electrode except for a portion of the semiconductor layers and the contact electrode, which is covered with the conductive adhesive layer.

10. The light-emitting element of claim 1, wherein the conductive adhesive layer has a smaller area than the bonding electrode, and
a first portion of the bonding electrode overlaps the conductive adhesive layer, and a second portion of the bonding electrode different from the first portion of the bonding electrode overlaps the first reflective layer.

11. The light-emitting element of claim 1, wherein the conductive adhesive layer further includes a first adhesive layer disposed between the contact electrode and the second reflective layer and a second adhesive layer disposed between the second reflective layer and the bonding electrode.

12. The light-emitting element of claim 11, wherein the conductive adhesive layer further includes a first barrier layer disposed between the second reflective layer and the second adhesive layer and a second barrier layer disposed between the second adhesive layer and the bonding electrode.

13. A display device comprising:
a pixel including:
a first electrode;
a second electrode; and
a light-emitting element connected between the first electrode and the second electrode, the light-emitting element including:
semiconductor layers including a first semiconductor layer, a light-emitting layer and a second semiconductor layer;
a contact electrode disposed between the semiconductor layers and the first electrode;
a bonding electrode disposed between the contact electrode and the first electrode;
a first reflective layer which is disposed between the contact electrode and the bonding electrode and in which an opening overlapping a first portion of the contact electrode and the bonding electrode is defined, the first reflective layer overlapping a second portion of the contact electrode, which is different from the first portion, and the bonding electrode; and
a conductive adhesive layer disposed in the opening of the first reflective layer between the contact electrode and the bonding electrode, the conductive adhesive layer including:
a second reflective layer including a material different from a material of the first reflective layer,
wherein a surface of the semiconductor layers and the contact electrode, which faces the first electrode, is covered with the first reflective layer and the conductive adhesive layer.

14. The display device of claim 13, wherein the first reflective layer includes a distributed Bragg reflector which reflects light of a wavelength band of light generated from the light-emitting layer and transmits infrared rays, and
the second reflective layer includes metal.

15. The display device of claim 13, wherein the conductive adhesive layer is filled in the opening of the first reflective layer, and
the surface of the semiconductor layers and the contact electrode, which is next to the bonding electrode, is completely covered with the first reflective layer and the conductive adhesive layer.

16. The display device of claim 13, wherein the light-emitting element further includes:
an insulating layer surrounding sides of the semiconductor layers; and
a third reflective layer surrounding the sides of the semiconductor layers with the insulating layer interposed therebetween and including metal.

17. A method of fabricating a light-emitting element, the method comprising:
sequentially forming semiconductor layers and a contact electrode on a substrate, the semiconductor layers including a first semiconductor layer, a light-emitting layer and a second semiconductor layer;
forming a first reflective layer on the semiconductor layers and the contact electrode;
defining an opening in the first reflective layer so that a portion of the contact electrode is exposed;
forming a conductive adhesive layer, which includes a second reflective layer, inside the opening; and
forming a bonding electrode on the first reflective layer and the conductive adhesive layer,
wherein the first reflective layer and the second reflective layer include different materials from each other.

18. The method of claim 17, wherein the first reflective layer includes a distributed Bragg reflector, and
the second reflective layer includes metal.

19. The method of claim 17, further comprising:
before forming the first reflective layer, forming an insulating layer covering the semiconductor layers and the contact electrode; and
etching the insulating layer to expose at least a portion of the contact electrode.

20. The method of claim 19, further comprising forming a third reflective layer on at least a portion of the insulating layer to surround sides of the semiconductor layers and the contact electrode.

21. An electronic device comprising:
a display device comprising:
a pixel including:
a first electrode;
a second electrode; and
a light-emitting element connected between the first electrode and the second electrode, the light-emitting element including:
semiconductor layers including a first semiconductor layer, a light-emitting layer and a second semiconductor layer;
a contact electrode disposed between the semiconductor layers and the first electrode;
a bonding electrode disposed between the contact electrode and the first electrode;
a first reflective layer which is disposed between the contact electrode and the bonding electrode and in which an opening overlapping a first portion of the contact electrode and the bonding electrode is defined, the first reflective layer overlapping a second portion of the contact electrode, which is different from the first portion, and the bonding electrode; and
a conductive adhesive layer disposed in the opening of the first reflective layer between the contact electrode and the bonding electrode, the conductive adhesive layer including:
a second reflective layer including a material different from a material of the first reflective layer,
wherein a surface of the semiconductor layers and the contact electrode, which faces the first electrode, is covered with the first reflective layer and the conductive adhesive layer.

22. The electronic device of claim 21, wherein the first reflective layer includes a distributed Bragg reflector which reflects light of a wavelength band of light generated from the light-emitting layer and transmits infrared rays, and
the second reflective layer includes metal.

23. The electronic device of claim 21, wherein the conductive adhesive layer is filled in the opening of the first reflective layer, and
the surface of the semiconductor layers and the contact electrode, which is next to the bonding electrode, is completely covered with the first reflective layer and the conductive adhesive layer.

24. The electronic device of claim 21, wherein the light-emitting element further includes:
an insulating layer surrounding sides of the semiconductor layers; and
a third reflective layer surrounding the sides of the semiconductor layers with the insulating layer interposed therebetween and including metal.
